(19) United States
(12) Patent Application Publication
(10) Pub. No.: US 2016/0056226 A1
(43) Pub. Date: Feb. 25, 2016

(54) WAFER LEVEL PACKAGE (WLP) INTEGRATED DEVICE COMPRISING ELECTROMAGNETIC (EM) PASSIVE DEVICE IN REDISTRIBUTION PORTION, AND RADIO FREQUENCY (RF) SHIELD

(71) Applicant: QUALCOMM Incorporated, San Diego, CA (US)

(72) Inventors: Young Kyu Song, San Diego, CA (US); Kyu-Pyung Hwang, San Diego, CA (US)

(21) Appl. No.: 14/468,035

(22) Filed: Aug. 25, 2014

(51) Int. Cl. H01L 49/02; H01L 23/00

(52) U.S. Cl. CPC H01L 28/10; H01L 24/02; H01L 23/564; H01L 2224/0233

(57) ABSTRACT

Some novel features pertain to an integrated device that includes a substrate, several lower level metal layers, several lower level dielectric layers, and a redistribution portion. The redistribution portion includes a first dielectric layer that includes a first dielectric thickness, and an electromagnetic (EM) passive device that includes a first redistribution interconnect. The first redistribution interconnect includes a first redistribution thickness, where the first dielectric thickness is at least about 2 times greater than the first redistribution thickness. In some implementations, the redistribution portion includes a radio frequency (RF) shield. In some implementations, the RF shield is located between a passivation layer and the several lower level dielectric layers. The RF shield is located between the EM passive device and the several lower level dielectric layers. The RF shield is electrically coupled to an interconnect configured to provide an electrical path for a ground signal.

### BACKGROUND

1. Field

Various features relate to an integrated device that includes an electromagnetic (EM) passive device in a redistribution portion, and radio frequency (RF) shield.

2. Background

A typical die is manufactured by depositing several metal layers and several dielectric layers on top of a substrate. The substrate, metal layers and dielectric layers are what form the circuit elements of the die. Multiple dies are usually manufactured on a wafer. FIG. 1 illustrates a plan view of a wafer 100 that includes several uncut dies 102. Each uncut die includes a substrate, metal layers and dielectric layers. The wafer 100 is then cut into individual/single dies. FIG. 1 also illustrates vertical and horizontal scribe lines 102-104. Scribe lines are portions of the wafer 100 that are cut in order to manufacture the individual dies (e.g., die 102).

FIG. 2 illustrates a side view of a die 200 from a wafer. The die 200 includes a substrate 201, several lower level metal and dielectric layers 202, a first pad 204, a second pad 206, a dielectric layer 208.

FIG. 3 illustrates a conventional integrated package that includes a die and an inductor. As shown in FIG. 3, the integrated package 300 includes a substrate 302, a die (e.g., chip) 304, a first set of solder balls 306, an inductor 308, a second set of solder ball 310. The die 304 may be the die 200 of FIG. 2. The substrate 302 may include traces, vias, and/or pads (which are not shown). The die 304 is coupled to a first surface (e.g., top surface) of the substrate 302 through the first set of solder balls 306. The second set of solder balls 310 is coupled to a second surface (e.g., bottom surface) of the substrate 302. The inductor 308 is integrated in the substrate 302.

One major drawback of the integrated package shown in FIG. 3 is that it creates an integrated device with a form factor that may be too large for the needs of mobile computing devices. For example, the location of the inductor 308 may limit how small the integrated package can be. This may result in a package that is either too large and/or too thick. That is, the integrated package configuration shown in FIG. 3 may be too thick and/or have a surface area that is too large to meet the needs and/or requirements of mobile computing devices. However, the problem with putting the inductor 308 closer to the die 304 can result in the inductor 308 interfering with the circuit of the die 304.

Therefore, there is a need for an integrated device that includes an improved configuration for an electromagnetic passive device. Ideally, such an integrated device will have a better form factor, while at the same time meeting the needs and/or requirements of mobile computing devices. Moreover, such an improved configuration of the electromagnetic passive device would provide better integrated device performance (e.g., better signal, better channel, better electrical speed performance) without interfering with the circuit of an integrated device.

### SUMMARY

Various features, apparatus and methods described herein provide an integrated device that includes an electromagnetic (EM) passive device in a redistribution portion, and radio frequency (RF) shield.

A first example provides an integrated device that includes a substrate, several lower level metal layers, several lower level dielectric layers, and a redistribution portion. The redistribution portion includes a first dielectric layer comprising a first dielectric thickness, and an electromagnetic (EM) passive devicecomprising a first redistribution interconnect, where the first redistribution interconnect comprises a first redistribution thickness, and the first dielectric thickness is at least about 2 times (2×) greater than the first redistribution thickness.

According to an aspect, the integrated further comprises a radio frequency (RF) shield.

According to one aspect, the RF shield is located between a passivation layer and the plurality of lower level dielectric layers.

According to an aspect, the RF shield is located between the EM passive device and the plurality of lower level dielectric layers.

According to one aspect, the RF shield is coupled to an interconnect configured to provide an electrical path for a ground signal.

According to an aspect, the EM passive device portion further comprises a second redistribution interconnect.

According to one aspect, the integrated device is one of at least a die and/or a wafer level package integrated device.

According to an aspect, the EM passive device includes one of at least an inductor, a coupler and/or a transformer.

According to one aspect, the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A second example provides a method for fabricating an integrated device. The method provides a substrate. The method provides forms several lower level metal layers. The method forms several lower level dielectric layers. The method forms a redistribution portion, where forming the redistribution portion includes forming a first dielectric layer comprising a first dielectric thickness, and forming an electromagnetic (EM) passive device by forming a first redistribution interconnect and a second redistribution interconnect. The first redistribution interconnect includes a first redistribution thickness. The first dielectric thickness is at least about 2 times (2×) greater than the first redistribution thickness.

According to an aspect, the method further comprises forming a radio frequency (RF) shield.

According to one aspect, the RF shield is located between a passivation layer and the plurality of lower level dielectric layers.

According to an aspect, the RF shield is located between the EM passive device and the plurality of lower level dielectric layers.

According to one aspect, the RF shield is coupled to an interconnect configured to provide an electrical path for a ground signal.

According to one aspect, the integrated device is one of at least a die and/or a wafer level package integrated device.

According to an aspect, the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

A third example provides an integrated device that includes a substrate, a plurality of lower level metal layers, a plurality of lower level dielectric layers, a radio frequency (RF) shield, and a redistribution portion. The redistribution portion includes a first dielectric layer and an electromagnetic (EM) passive device comprising a first redistribution interconnect.

According to an aspect, the RF shield is coupled to an interconnect configured to provide an electrical path for a ground signal.

According to one aspect, the integrated device is one of at least a die and/or a wafer level package integrated device.

According to an aspect, the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

### DRAWINGS

Various features, nature and advantages may become apparent from the detailed description set forth below when taken in conjunction with the drawings in which like reference characters identify correspondingly throughout.

FIG. 1 illustrates a wafer that includes uncut dies.

FIG. 2 illustrates a profile view of a die.

FIG. 3 illustrates an example of a package that includes a die and an inductor.

FIG. 4 illustrates an exemplary integrated device that includes an electromagnetic passive device in a redistribution portion, and a radio frequency (RF) shield.

FIG. 5 illustrates a plan view of an exemplary inductor.

FIG. 6 illustrates a plan view of an exemplary RF shield.

FIG. 7 illustrates another exemplary integrated device that includes an electromagnetic passive device in a redistribution portion, and a radio frequency (RF) shield.

FIG. 8 illustrates yet another exemplary integrated device that includes an electromagnetic passive device in a redistribution portion, and a radio frequency (RF) shield.

FIG. 9 illustrates another exemplary integrated device that includes an electromagnetic passive device in a redistribution portion, and a radio frequency (RF) shield.

FIG. 10 illustrates another exemplary integrated device that includes an electromagnetic passive device in a redistribution portion, and a radio frequency (RF) shield.

FIG. 11 illustrates yet another exemplary integrated device that includes an electromagnetic passive device in a redistribution portion, and a radio frequency (RF) shield.

FIG. 12 illustrates another exemplary integrated device that includes an electromagnetic passive device in a redistribution portion, and a radio frequency (RF) shield.

FIG. 13 (comprising 13A-13E) illustrates an exemplary sequence for providing/fabricating an integrated device that includes an electromagnetic passive device in a redistribution portion, and a radio frequency (RF) shield.

FIG. 14 (comprising 14A-14E) illustrates an exemplary sequence for providing/fabricating an integrated device that includes an electromagnetic passive device in a redistribution portion, and a radio frequency (RF) shield.

FIG. 15 illustrates an exemplary method for providing/fabricating an integrated device that includes an electromagnetic passive device in a redistribution portion, and a radio frequency (RF) shield.

FIG. 16 illustrates an example of a metal layer (e.g., interconnect) formed using a semi-additive patterning (SAP) process.

FIG. 17 illustrates an example of metal layers formed using a damascene process.

FIG. 18 illustrates an example of a semi-additive patterning (SAP) process.

FIG. 19 illustrates an example of flow diagram of a semi-additive patterning (SAP) process.

FIG. 20 illustrates an example of a damascene process.

FIG. 21 illustrates an example of a flow diagram of a damascene process.

FIG. 22 illustrates various electronic devices that may integrate a semiconductor device, a die, an integrated circuit and/or PCB described herein.

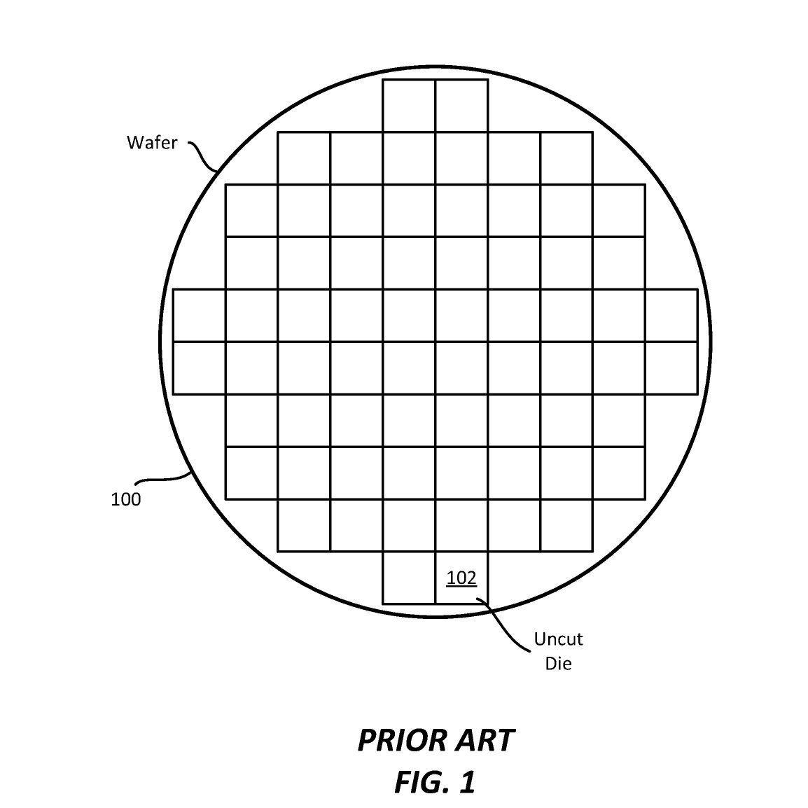

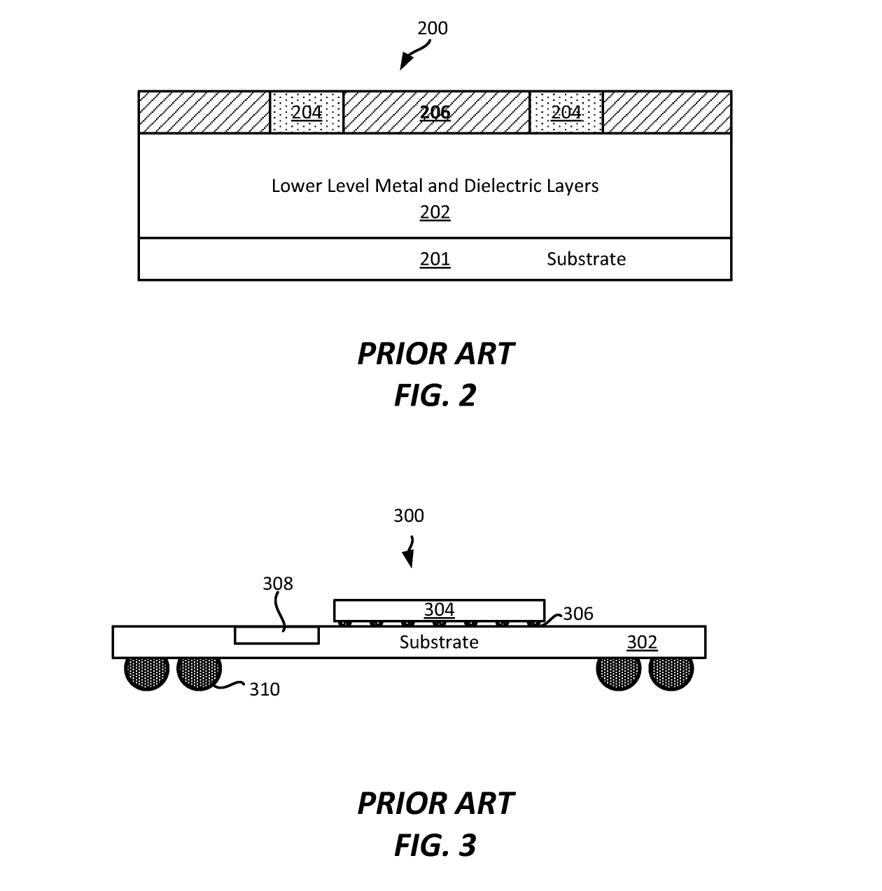

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some novel features pertain to an integrated device that includes a substrate, several lower level metal layers, several lower level dielectric layers, and a redistribution portion. The redistribution portion includes a first dielectric layer that includes a first dielectric thickness, and a an electromagnetic (EM) passive device that includes a first redistribution interconnect. The first redistribution interconnect includes a first redistribution thickness, where the first dielectric thickness is at least about 2 times (2×) greater than the first redistribution thickness. In some implementations, the redistribution portion includes a radio frequency (RF) shield. In some implementations, the RF shield is located between a passivation layer and the several lower level dielectric layers. In some implementations, the RF shield is located between the an electromagnetic passive device and the several lower level dielectric layers. In some implementations, the RF shield is coupled to an interconnect configured to provide an electrical path for a ground signal.

### TERMS AND DEFINITIONS

An interconnect is an element or component that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that provides an electrical path for a signal (e.g., data signal, ground signal, power signal). An interconnect may include more than one element/component.

A redistribution layer (or a redistribution metal layer) is a metal layer of a redistribution portion of an integrated device. A redistribution layer may include one or more redistribution interconnects, which are formed on the same metal layer of the redistribution portion. A redistribution portion of an integrated device may include several redistribution layers, each redistribution layer may include one or more redistribution interconnects. Thus, for example, a redistribution portion may include a first redistribution interconnect on a first redistribution layer, and a second redistribution interconnect on a second redistribution layer that is different than the first redistribution layer.

An electromagnetic (EM) passive device is a passive device that produces a magnetic field when a current/electricity passes through the device, or produces a current/electricity in the presence of a magnetic field. An EM passive device may include an inductor (e.g., spiral inductor), a coupler, and/or a transformer. A coupler or transformer may include two or more inductors.

### Exemplary Integrated Device Comprising Electromagnetic (EM) Passive Device and Radio Frequency (RF) Shield

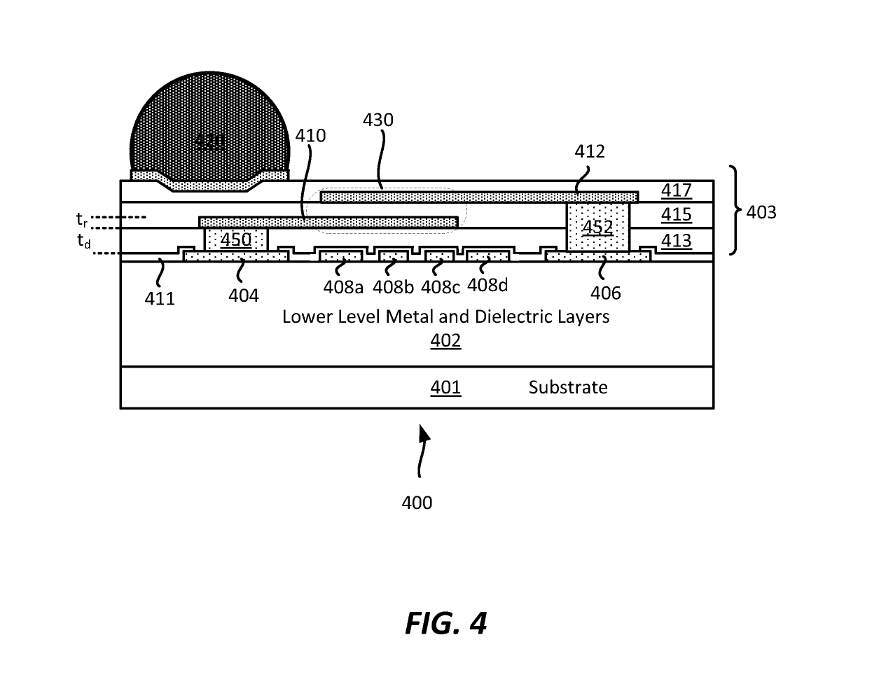

FIG. 4 illustrates a profile view of an integrated device 400 that includes an electromagnetic (EM) passive device and a radio frequency (RF) shield. In some implementations, the integrated device 400 is one of at least a die, and/or a wafer level package integrated device. The integrated device 400 includes a substrate 401, lower level metal and dielectric layers 402, and a redistribution portion 403. In some implementations, the substrate 401 is a silicon substrate and/or wafer (e.g., silicon wafer). The lower level metal and dielectric layers 402 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 402 include traces and/or vias. The lower level metal and dielectric layers 402 also include one or more dielectric layers. In some implementations, the lower level metal and dielectric layers 402 are provided and/or formed using a back end of line (BEOL) process.

The integrated device 400 also includes a first pad 404, a second pad 406, metal layers 408 (which includes metal layers 408a, 408b, 408c, 408d), and a passivation layer 411. In some implementations, the first pad 404, the second pad 406, and the metal layers 408 are referred to as the top metal layer of the integrated device. The first and second pads 404 and 406 are coupled to respective lower metals in the lower metal and dielectric layers 402.

The redistribution portion 403 includes a first via 450, a second via 452, a first dielectric layer 413, a second dielectric layer 415, a third dielectric layer 417, a first redistribution interconnect 410, a second redistribution interconnect 412, and an under bump metallization (UBM) layer 414. The first redistribution interconnect 410 is electrically coupled to the first via 450. The first via 450 is electrically coupled to the first pad 404. The second redistribution interconnect 412 is electrically coupled to the second via 452. The second via 452 is electrically coupled to the second pad 406. The second via 452 has a greater height than the first via 450. The second via 452 traverses the first and second dielectric layers 413 and 415. The first and second interconnects 410 and 412 have a relatively flat shape.

As shown in FIG. 4, a portion of the first redistribution interconnect 410 overlaps (e.g., vertically overlaps) with a portion of the second redistribution interconnect 412. In some implementations, the overlapping (e.g., vertically overlapping) portions of the first and second redistribution interconnects 410 and/or 412 are configured to form and/or define an electromagnetic (EM) passive device 430 in the redistribution portion 403. The EM passive device 430 may be defined by either or both the redistribution interconnects 410 and/or 412. The EM passive device 430 may include one of at least an inductor, a coupler and/or a transfer. For example, the redistribution interconnects 410 or 412 may be configured as an inductor. In another example, the combination of the redistribution interconnects 410 and 412 may be configured as a coupler or transformer.

The first, second and third dielectric layers 413, 415 and 417 are insulation layers. In some implementations, the first, second and third dielectric layers 413, 415 and 417 may be polyimide layers. For example, the first, second and third dielectric layers 413, 415 and 417 may be Polybenzoxazole (PbO) layers and/or polymer layers.

FIG. 4 illustrates that the first dielectric layer 413 has a first dielectric thickness (t_{d}) and the first redistribution interconnect 410 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 430 is sufficiently away or offset from components (e.g., active circuits) of the integrated device 400, and/or to ensure that the EM passive device 430 does not affect other components of the integrated device 400. This results in better EM passive device performance in the integrated device 400. In some implementations, the thickness of other redistribution layers may be similar or about the same as the first redistribution thickness.

The performance of the EM passive device 430 may further be improved by providing a radio frequency (RF) shield in the integrated device 400. FIG. 4 illustrates metal layers 408 (comprising metal layers 408a, 408b, 408c, and 408d) which are configured to operate as a RF shield in the integrated device 400. In some implementations, the RF shield formed by the metal layers 408 may be at least partially vertically aligned (e.g., partially, substantially, or completely vertically aligned) with the EM passive device 430. An example of an RF shield design is further described in FIG. 6. In some implementations, the RF shield is electrically coupled to an interconnect configured to provide an electrical path for a ground signal. In such instance, the RF shield, comprising the metal layers 408, is coupled to one or more redistribution interconnects and/or a under bump metallization (UBM) layer.

FIG. 4 further illustrates a solder ball 420 coupled to the UBM layer 414. However, in some implementations, the solder ball 420 may be directly coupled to a redistribution interconnect. For example, the solder ball 420 may be directly coupled to the second redistribution interconnect 412.

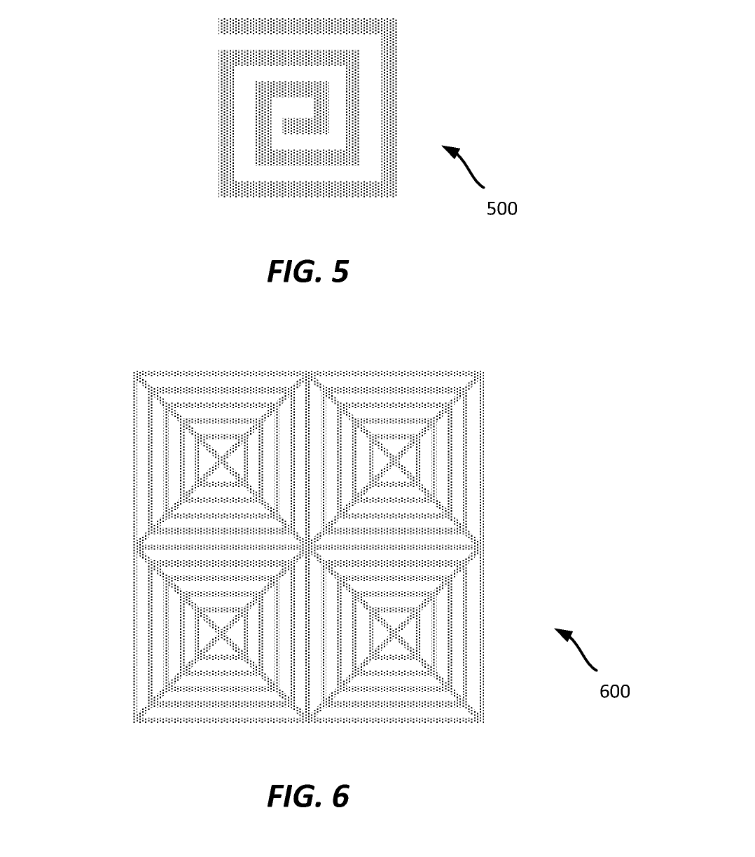

FIG. 5 illustrates a plan view of an exemplary electromagnetic (EM) passive device 500 that may be implemented in a redistribution portion of an integrated device. The EM passive device 500 shows is a spiral inductor. However, different implementations may use different shapes and/or configurations of an inductor. In some implementations, two or more inductors (e.g., spiral inductors) may be used in combination to form a coupler or a transformed in a redistribution portion of an integrated device.

FIG. 6 illustrates a plan view of an exemplary radio frequency (RF) shield 600 that may be implemented in an integrated device. It should be noted that the RF shield 600 is merely one design of many possible designs of an RF shield. As such, an RF shield implemented in an integrated device should not be limited by the RF shield 600 of FIG. 6.

### Exemplary Integrated Device Comprising Electromagnetic (EM) Passive Device and Radio Frequency (RF) Shield

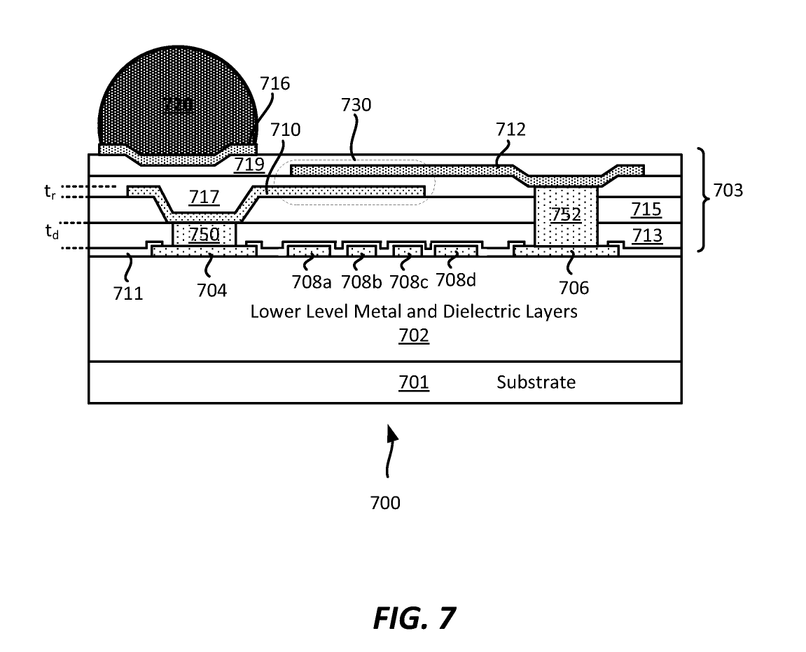

FIG. 7 illustrates a profile view of an integrated device 700 that includes an electromagnetic (EM) passive device and a radio frequency (RF) shield. In some implementations, the integrated device 700 is one of at least a die, and/or a wafer level package integrated device. The integrated device 700 includes a substrate 701, lower level metal and dielectric layers 702, and a redistribution portion 703. In some implementations, the substrate 701 is a silicon substrate and/or wafer (e.g., silicon wafer). The lower level metal and dielectric layers 702 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 702 include traces and/or vias. The lower level metal and dielectric layers 702 also include one or more dielectric layers. In some implementations, the lower level metal and dielectric layers 702 are provided and/or formed using a back end of line (BEOL) process.

The integrated device 700 also includes a first pad 704, a second pad 706, metal layers 708 (which includes metal layers 708a, 708b, 708c, 708d), and a passivation layer 711. In some implementations, the first pad 704, the second pad 706, and the metal layers 708 are referred to as the top metal layer of the integrated device. The first and second pads 704 and 706 are coupled to respective lower metals in the lower metal and dielectric layers 702.

The redistribution portion 703 includes a first via 750, a second via 752, a first dielectric layer 713, a second dielectric layer 715, a third dielectric layer 717, a fourth dielectric layer 719, a first redistribution interconnect 710, a second redistribution interconnect 712, and an under bump metallization (UBM) layer 714. The first redistribution interconnect 710 is electrically coupled to the first via 750. The first via 750 is electrically coupled to the first pad 704. The second redistribution interconnect 712 is electrically coupled to the second via 752. The second via 752 is electrically coupled to the second pad 706. The second via 752 has a greater height than the first via 750. The second via 752 traverses the first and second dielectric layers 713 and 715. The first and second interconnects 710 and 712 have a shape that is at least partially U or V shaped.

As shown in FIG. 7, a portion of the first redistribution interconnect 710 overlaps (e.g., vertically overlaps) with a portion of the second redistribution interconnect 712. In some implementations, the overlapping (e.g., vertically overlapping) portions of the first and second redistribution interconnects 710 and/or 712 are configured to form and/or define an electromagnetic (EM) passive device 730 in the redistribution portion 703. The EM passive device 730 may be defined by either or both the redistribution interconnects 710 and/or 712. The EM passive device 730 may include one of at least an inductor, a coupler and/or a transfer. For example, the redistribution interconnects 710 or 712 may be configured as an inductor. In another example, the combination of the redistribution interconnects 710 and 712 may be configured as a coupler or transformer.

The first, second, third and fourth dielectric layers 713, 715, 717 and 719 are insulation layers. In some implementations, the first, second, third and fourth dielectric layers 713, 715, 717 and 719 may be polyimide layers. For example, the first, second and third dielectric layers 713, 715 and 717 may be Polybenzoxazole (PbO) layers and/or polymer layers.

FIG. 7 illustrates that the first dielectric layer 713 has a first dielectric thickness (t_{d}) and the first redistribution interconnect 710 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 730 is sufficiently away or offset from components (e.g., active circuits) of the integrated device 700, and/or to ensure that the EM passive device 730 does not affect other components of the integrated device 700. This results in better EM passive device performance in the integrated device 700. In some implementations, the thickness of other redistribution layers may be similar or about the same as the first redistribution thickness.

The performance of the EM passive device 730 may further be improved by providing a radio frequency (RF) shield in the integrated device 700. FIG. 7 illustrates metal layers 708 (comprising metal layers 708a, 708b, 708c, and 708d) which are configured to operate as a RF shield in the integrated device 700. In some implementations, the RF shield formed by the metal layers 708 may be at least partially vertically aligned (e.g., partially, substantially, or completely vertically aligned) with the EM passive device 730. In some implementations, the RF shield is electrically coupled to an interconnect configured to provide an electrical path for a ground signal. In such instance, the RF shield, comprising the metal layers 708, is coupled to one or more redistribution interconnects and/or a under bump metallization (UBM) layer.

FIG. 7 further illustrates a solder ball 720 coupled to the UBM layer 714. However, in some implementations, the solder ball 720 may be directly coupled to a redistribution interconnect. For example, the solder ball 720 may be directly coupled to the second redistribution interconnect 712.

### Exemplary Integrated Device Comprising Electromagnetic (EM) Passive Device and Radio Frequency (RF) Shield

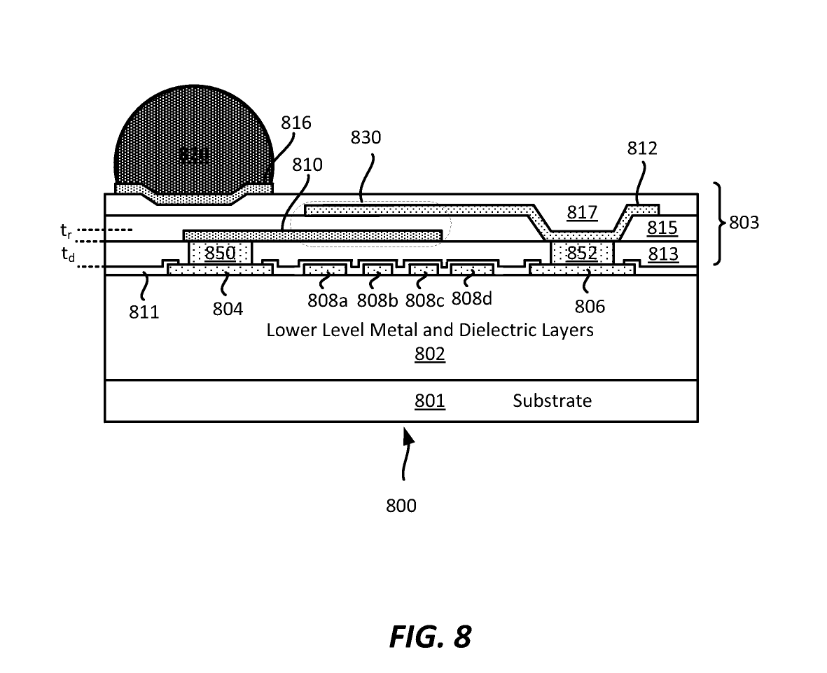

FIG. 8 illustrates a profile view of an integrated device 800 that includes an electromagnetic (EM) passive device and a radio frequency (RF) shield. In some implementations, the integrated device 800 is one of at least a die, and/or a wafer level package integrated device. The integrated device 800 includes a substrate 801, lower level metal and dielectric layers 802, and a redistribution portion 803. In some implementations, the substrate 801 is a silicon substrate and/or wafer (e.g., silicon wafer). The lower level metal and dielectric layers 802 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 802 include traces and/or vias. The lower level metal and dielectric layers 802 also include one or more dielectric layers. In some implementations, the lower level metal and dielectric layers 802 are provided and/or formed using a back end of line (BEOL) process.

The integrated device 800 also includes a first pad 804, a second pad 806, metal layers 808 (which includes metal layers 808a, 808b, 808c, 808d), and a passivation layer 811. In some implementations, the first pad 804, the second pad 806, and the metal layers 808 are referred to as the top metal layer of the integrated device. The first and second pads 804 and 806 are coupled to respective lower metals in the lower metal and dielectric layers 802.

The redistribution portion 803 includes a first via 850, a second via 852, a first dielectric layer 813, a second dielectric layer 815, a third dielectric layer 817, a first redistribution interconnect 810, a second redistribution interconnect 812, and an under bump metallization (UBM) layer 814. The first redistribution interconnect 810 is electrically coupled to the first via 850. The first via 850 is electrically coupled to the first pad 804. The second redistribution interconnect 812 is electrically coupled to the second via 852. The second via 852 is electrically coupled to the second pad 806. The first via 850 and the second via 852 have a height that is about the same. The first redistribution interconnect 810 has a roughly flat shape, whereas the second redistribution 812 has a shape that is at least partially U or V shaped.

As shown in FIG. 8, a portion of the first redistribution interconnect 810 overlaps (e.g., vertically overlaps) with a portion of the second redistribution interconnect 812. In some implementations, the overlapping (e.g., vertically overlapping) portions of the first and second redistribution interconnects 810 and/or 812 are configured to form and/or define an electromagnetic (EM) passive device 830 in the redistribution portion 803. The EM passive device 830 may be defined by either or both the redistribution interconnects 810 and/or 812. The EM passive device 830 may include one of at least an inductor, a coupler and/or a transfer. For example, the redistribution interconnects 810 or 812 may be configured as an inductor. In another example, the combination of the redistribution interconnects 810 and 812 may be configured as a coupler or transformer.

The first, second and third dielectric layers 813, 815 and 817 are insulation layers. In some implementations, the first, second and third dielectric layers 813, 815 and 817 may be polyimide layers. For example, the first, second and third dielectric layers 813, 815 and 817 may be Polybenzoxazole (PbO) layers and/or polymer layers.

FIG. 8 illustrates that the first dielectric layer 813 has a first dielectric thickness (t_{d}) and the first redistribution interconnect 810 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 830 is sufficiently away or offset from components (e.g., active circuits) of the integrated device 800, and/or to ensure that the EM passive device 830 does not affect other components of the integrated device 800. This results in better EM passive device performance in the integrated device 800. In some implementations, the thickness of other redistribution layers may be similar or about the same as the first redistribution thickness.

The performance of the EM passive device 830 may further be improved by providing a radio frequency (RF) shield in the integrated device 800. FIG. 8 illustrates metal layers 808 (comprising metal layers 808a, 808b, 808c, and 808d) which are configured to operate as a RF shield in the integrated device 800. In some implementations, the RF shield formed by the metal layers 808 may be at least partially vertically aligned (e.g., partially, substantially, or completely vertically aligned) with the EM passive device 830. In some implementations, the RF shield is electrically coupled to an interconnect configured to provide an electrical path for a ground signal. In such instance, the RF shield, comprising the metal layers 808, is coupled to one or more redistribution interconnects and/or a under bump metallization (UBM) layer.

FIG. 8 further illustrates a solder ball 820 coupled to the UBM layer 814. However, in some implementations, the solder ball 820 may be directly coupled to a redistribution interconnect. For example, the solder ball 820 may be directly coupled to the second redistribution interconnect 812.

### Exemplary Integrated Device Comprising Electromagnetic (EM) Passive Device and Radio Frequency (RF) Shield

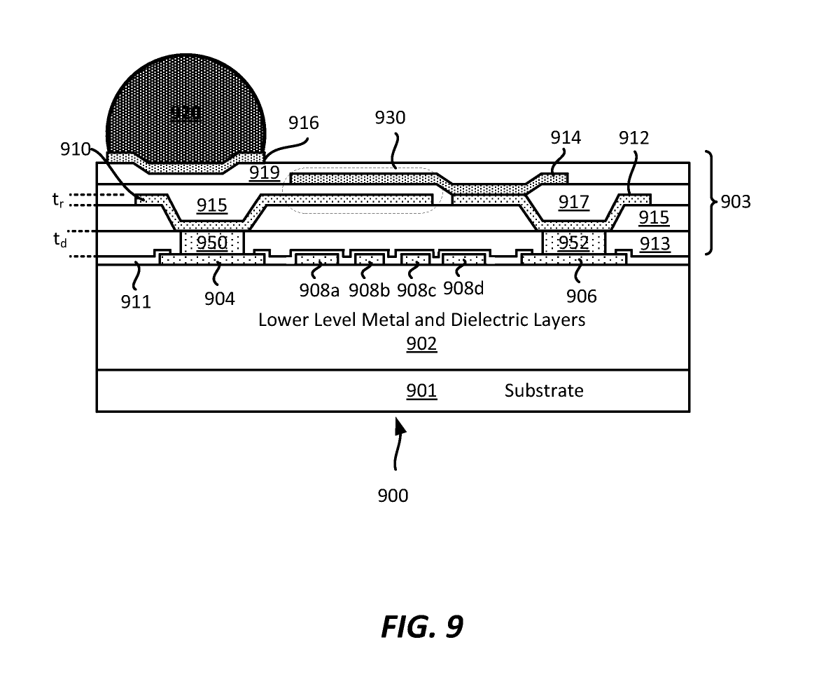

FIG. 9 illustrates a profile view of an integrated device 900 that includes an electromagnetic (EM) passive device and a radio frequency (RF) shield. In some implementations, the integrated device 900 is one of at least a die, and/or a wafer level package integrated device. The integrated device 900 includes a substrate 901, lower level metal and dielectric layers 902, and a redistribution portion 903. In some implementations, the substrate 901 is a silicon substrate and/or wafer (e.g., silicon wafer). The lower level metal and dielectric layers 902 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 902 include traces and/or vias. The lower level metal and dielectric layers 902 also include one or more dielectric layers. In some implementations, the lower level metal and dielectric layers 902 are provided and/or formed using a back end of line (BEOL) process.

The integrated device 900 also includes a first pad 904, a second pad 906, metal layers 908 (which includes metal layers 908a, 908b, 908c, 908d), and a passivation layer 911. In some implementations, the first pad 904, the second pad 906, and the metal layers 908 are referred to as the top metal layer of the integrated device. The first and second pads 904 and 906 are coupled to respective lower metals in the lower metal and dielectric layers 902.

The redistribution portion 903 includes a first via 950, a second via 952, a first dielectric layer 913, a second dielectric layer 915, a third dielectric layer 917, a fourth dielectric layer 919, a first redistribution interconnect 910, a second redistribution interconnect 912, a third redistribution interconnect 914, and an under bump metallization (UBM) layer 916. The first redistribution interconnect 910 is electrically coupled to the first via 950. The first via 950 is electrically coupled to the first pad 904. The third redistribution interconnect 914 is electrically coupled to the second redistribution interconnect 912. The second redistribution interconnect 912 is electrically coupled to the second via 952. The second via 952 is electrically coupled to the second pad 906. The first via 950 and the second via 952 have a height that is about the same. The first, second, and third redistribution interconnects 910, 912 and 914 have a shape that is at least partially U or V shaped.

As shown in FIG. 9, a portion of the first redistribution interconnect 910 overlaps (e.g., vertically overlaps) with a portion of the third redistribution interconnect 914. In some implementations, the overlapping (e.g., vertically overlapping) portions of the first and third redistribution interconnects 910 and/or 914 are configured to form and/or define an electromagnetic (EM) passive device 930 in the redistribution portion 903. The EM passive device 930 may be defined by either or both the redistribution interconnects 910 and/or 914. The EM passive device 930 may include one of at least an inductor, a coupler and/or a transfer. For example, the redistribution interconnects 910 or 914 may be configured as an inductor. In another example, the combination of the redistribution interconnects 910 and 914 may be configured as a coupler or transformer.

The first, second, third and fourth dielectric layers 913, 915, 917 and 919 are insulation layers. In some implementations, the first, second, third and fourth dielectric layers 913, 915, 917 and 919 may be polyimide layers. For example, the first, second and third dielectric layers 913, 915, 917 and 919 may be Polybenzoxazole (PbO) layers and/or polymer layers.

FIG. 9 illustrates that the first dielectric layer 913 has a first dielectric thickness (t_{d}) and the first redistribution interconnect 910 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 930 is sufficiently away or offset from components (e.g., active circuits) of the integrated device 900, and/or to ensure that the EM passive device 930 does not affect other components of the integrated device 900. This results in better EM passive device performance in the integrated device 900. In some implementations, the thickness of other redistribution layers may be similar or about the same as the first redistribution thickness.

The performance of the EM passive device 930 may further be improved by providing a radio frequency (RF) shield in the integrated device 900. FIG. 9 illustrates metal layers 908 (comprising metal layers 908a, 908b, 908c, and 908d) which are configured to operate as a RF shield in the integrated device 900. In some implementations, the RF shield formed by the metal layers 908 may be at least partially vertically aligned (e.g., partially, substantially, or completely vertically aligned) with the EM passive device 930. An example of an RF shield design is further described in FIG. 6. In some implementations, the RF shield is electrically coupled to an interconnect configured to provide an electrical path for a ground signal. In such instance, the RF shield, comprising the metal layers 908, is coupled to one or more redistribution interconnects and/or a under bump metallization (UBM) layer.

FIG. 9 further illustrates a solder ball 920 coupled to the UBM layer 914. However, in some implementations, the solder ball 920 may be directly coupled to a redistribution interconnect. For example, the solder ball 920 may be directly coupled to the second redistribution interconnect 912.

### Exemplary Integrated Device Comprising an Electromagnetic (EM) Passive Device and Radio Frequency (RF) Shield

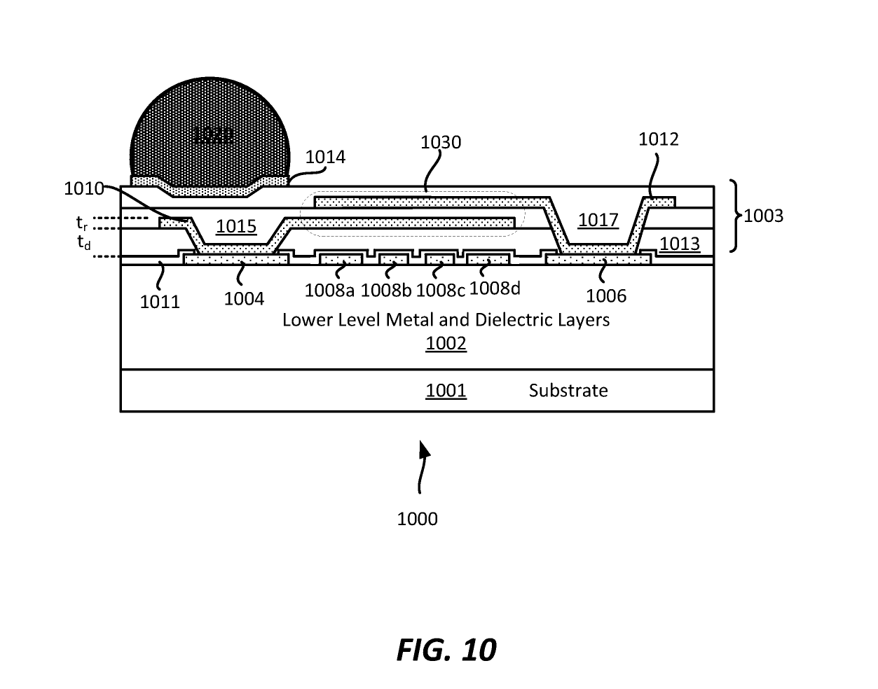

FIG. 10 illustrates a profile view of an integrated device 1000 that includes an electromagnetic (EM) passive device and a radio frequency (RF) shield. In some implementations, the integrated device 1000 is one of at least a die, and/or a wafer level package integrated device. The integrated device 1000 includes a substrate 1001, lower level metal and dielectric layers 1002, and a redistribution portion 1003. In some implementations, the substrate 1001 is a silicon substrate and/or wafer (e.g., silicon wafer). The lower level metal and dielectric layers 1002 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 1002 include traces and/or vias. The lower level metal and dielectric layers 1002 also include one or more dielectric layers. In some implementations, the lower level metal and dielectric layers 1002 are provided and/or formed using a back end of line (BEOL) process.

The integrated device 1000 also includes a first pad 1004, a second pad 1006, metal layers 1008 (which includes metal layers 1008a, 1008b, 1008c, 1008d), and a passivation layer 1011. In some implementations, the first pad 1004, the second pad 1006, and the metal layers 1008 are referred to as the top metal layer of the integrated device. The first and second pads 1004 and 1006 are coupled to respective lower metals in the lower metal and dielectric layers 1002.

The redistribution portion 1003 includes a first dielectric layer 1013, a second dielectric layer 1015, a third dielectric layer 1017, a first redistribution interconnect 1010, a second redistribution interconnect 1012, and an under bump metallization (UBM) layer 1014. The first redistribution interconnect 1010 is electrically coupled to the first pad 1004. The second redistribution interconnect 1012 is electrically coupled to the second pad 1006.

As shown in FIG. 10, a portion of the first redistribution interconnect 1010 overlaps (e.g., vertically overlaps) with a portion of the second redistribution interconnect 1012. In some implementations, the overlapping (e.g., vertically overlapping) portions of the first and second redistribution interconnects 1010 and/or 1012 are configured to form and/or define an electromagnetic (EM) passive device 1030 in the redistribution portion 1003. The EM passive device 1030 may be defined by either or both the redistribution interconnects 1010 and/or 1012. The EM passive device 1030 may include one of at least an inductor, a coupler and/or a transfer. For example, the redistribution interconnects 1010 or 1012 may be configured as an inductor. In another example, the combination of the redistribution interconnects 1010 and 1012 may be configured as a coupler or transformer.

The first, second and third dielectric layers 1013, 1015 and 1017 are insulation layers. In some implementations, the first, second and third dielectric layers 1013, 1015 and 1017 may be polyimide layers. For example, the first, second and third dielectric layers 1013, 1015 and 1017 may be Polybenzoxazole (PbO) layers and/or polymer layers.

FIG. 10 illustrates that the first dielectric layer 1013 has a first dielectric thickness (t_{d}) and the first redistribution interconnect 1010 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 1030 is sufficiently away or offset from components (e.g., active circuits) of the integrated device 1000, and/or to ensure that the EM passive device 1030 does not affect other components of the integrated device 1000. This results in better EM passive device performance in the integrated device 1000. In some implementations, the thickness of other redistribution layers may be similar or about the same as the first redistribution thickness.

The performance of the EM passive device 1030 may further be improved by providing a radio frequency (RF) shield in the integrated device 1000. FIG. 10 illustrates metal layers 1008 (comprising metal layers 1008a, 1008b, 1008c, and 1008d) which are configured to operate as a RF shield in the integrated device 1000. Specifically, the RF shield formed by the metal layers 1008, is located in the redistribution portion 1003 of the integrated device 1000. In some implementations, the RF shield formed by the metal layers 1008 may be at least partially vertically aligned (e.g., partially, substantially, or completely vertically aligned) with the EM passive device 1030. An example of an RF shield design is further described in FIG. 6. In some implementations, the RF shield is electrically coupled to an interconnect configured to provide an electrical path for a ground signal. In such instance, the RF shield, comprising the metal layers 1008, is coupled to one or more redistribution interconnects and/or a under bump metallization (UBM) layer.

FIG. 10 further illustrates a solder ball 1020 coupled to the UBM layer 1014. However, in some implementations, the solder ball 1020 may be directly coupled to a redistribution interconnect. For example, the solder ball 1020 may be directly coupled to the second redistribution interconnect 1012.

### Exemplary Integrated Device Comprising Electromagnetic (EM) Passive Device and Radio Frequency (RF) Shield

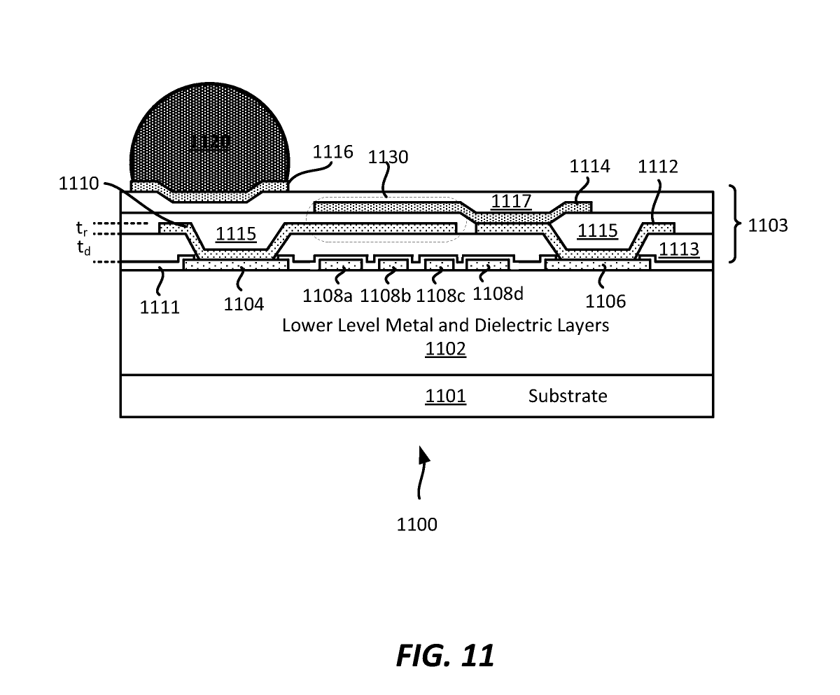

FIG. 11 illustrates a profile view of an integrated device 1100 that includes an electromagnetic (EM) passive device and a radio frequency (RF) shield. In some implementations, the integrated device 1100 is one of at least a die, and/or a wafer level package integrated device. The integrated device 1100 includes a substrate 1101, lower level metal and dielectric layers 1102, and a redistribution portion 1103. In some implementations, the substrate 1101 is a silicon substrate and/or wafer (e.g., silicon wafer). The lower level metal and dielectric layers 1102 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 1102 include traces and/or vias. The lower level metal and dielectric layers 1102 also include one or more dielectric layers. In some implementations, the lower level metal and dielectric layers 1102 are provided and/or formed using a back end of line (BEOL) process.

The integrated device 1100 also includes a first pad 1104, a second pad 1106, metal layers 1108 (which includes metal layers 1108a, 1108b, 1108c, 1108d), and a passivation layer 1111. In some implementations, the first pad 1104, the second pad 1106, and the metal layers 1108 are referred to as the top metal layer of the integrated device. The first and second pads 1104 and 1106 are coupled to respective lower metals in the lower metal and dielectric layers 1102.

The redistribution portion 1103 includes a first dielectric layer 1113, a second dielectric layer 1115, a third dielectric layer 1117, a first redistribution interconnect 1110, a second redistribution interconnect 1112, a third redistribution interconnect 1114, and an under bump metallization (UBM) layer 1116. The first redistribution interconnect 1110 is electrically coupled to the first pad 1104. The second redistribution interconnect 1112 is electrically coupled to the second pad 1106. In some implementations, the first and second redistribution interconnects 1110 and 1112 are on the same redistribution metal layer of the redistribution portion 1103. The third redistribution interconnect 1114 is electrically coupled to the second redistribution interconnect 1112.

As shown in FIG. 11, a portion of the first redistribution interconnect 1110 overlaps (e.g., vertically overlaps) with a portion of the third redistribution interconnect 1114. In some implementations, the overlapping (e.g., vertically overlapping) portions of the first and third redistribution interconnects 1110 and 1114 are configured to form and/or define an electromagnetic (EM) passive device 1130 in the redistribution portion 1103. The EM passive device 1130 may be defined by either or both the redistribution interconnects 1110 and/or 1114. The EM passive device 1130 may include one of at least an inductor, a coupler and/or a transformer. For example, the redistribution interconnects 1110 or 1114 may be configured as an inductor. In another example, the combination of the redistribution interconnects 1110 and 1114 may be configured as a coupler or transformer.

The first, second and third dielectric layers 1113, 1115 and 1117 are insulation layers. In some implementations, the first, second and third dielectric layers 1113, 1115 and 1117 may be polyimide layers. For example, the first, second and third dielectric layers 1113, 1115 and 1117 may be Polybenzoxazole (PbO) layers and/or polymer layers.

FIG. 11 illustrates that the first dielectric layer 1113 has a first dielectric thickness (t_{d}) and the first redistribution interconnect 1110 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 1130 is sufficiently away or offset from components (e.g., active circuits) of the integrated device 1100, and/or to ensure that the EM passive device 1130 does not affect other components of the integrated device 1100. This results in better EM passive device performance in the integrated device 1100. In some implementations, the thickness of other redistribution layers may be similar or about the same as the first redistribution thickness.

The performance of the EM passive device 1130 may further be improved by providing a radio frequency (RF) shield in the integrated device 1100. FIG. 11 illustrates metal layers 1108 (comprising metal layers 1108a, 1108b, 1108c, and 1108d) which are configured to operate as a RF shield in the integrated device 1100. Specifically, the RF shield formed by the metal layers 1108, is located in the redistribution portion 1103 of the integrated device 1100. In some implementations, the RF shield formed by the metal layers 1108 may be at least partially vertically aligned (e.g., partially, substantially, or completely vertically aligned). An example of an RF shield design was previously described in FIG. 6. In some implementations, the RF shield is electrically coupled to an interconnect configured to provide an electrical path for a ground signal. In such instance, the RF shield, comprising the metal layers 1108, is coupled to one or more redistribution interconnects and/or a under bump metallization (UBM) layer.

FIG. 11 further illustrates a solder ball 1120 coupled to the UBM layer 1116. However, in some implementations, the solder ball 1120 may be directly coupled to a redistribution interconnect. For example, the solder ball 1120 may be directly coupled to the third redistribution interconnect 1114.

### Exemplary Integrated Device Comprising Electromagnetic (EM) Passive Device and Radio Frequency (RF) Shield

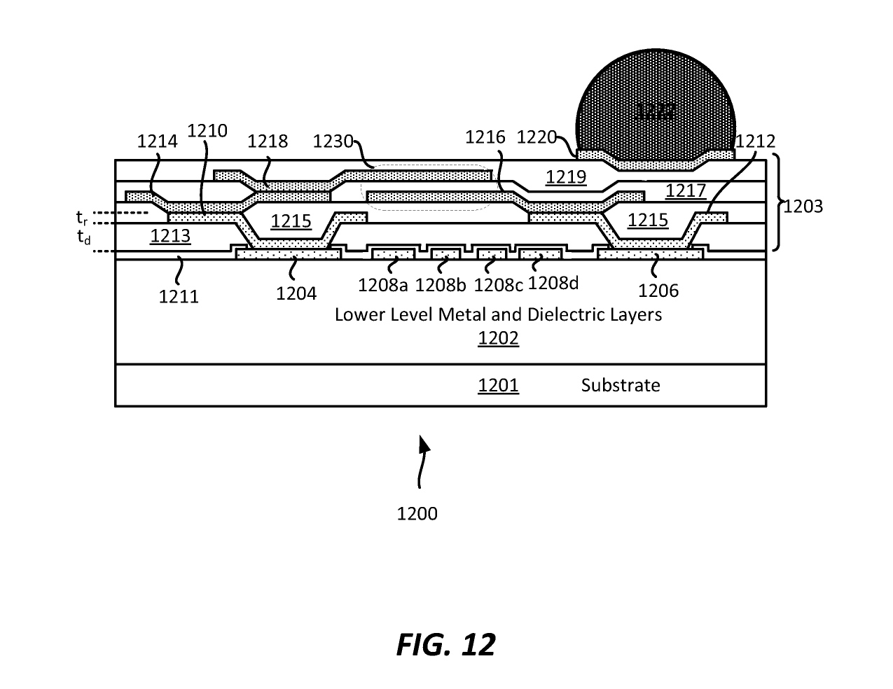

FIG. 12 illustrates a profile view of an integrated device 1200 that includes an electromagnetic (EM) passive device and a radio frequency (RF) shield. In some implementations, the integrated device 1200 is one of at least a die, and/or a wafer level package integrated device. The integrated device 1200 includes a substrate 1201, lower level metal and dielectric layers 1202, and a redistribution portion 1203. In some implementations, the substrate 1201 is a silicon substrate and/or wafer (e.g., silicon wafer). The lower level metal and dielectric layers 1202 include lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 1202 include traces and/or vias. The lower level metal and dielectric layers 1202 also include one or more dielectric layers. In some implementations, the lower level metal and dielectric layers 1202 are provided and/or formed using a back end of line (BEOL) process.

The integrated device 1200 also includes a first pad 1204, a second pad 1206, metal layers 1208 (which includes metal layers 1208a, 1208b, 1208c, 1208d), and a passivation layer 1211. In some implementations, the first pad 1204, the second pad 1206, and the metal layers 1208 are referred to as the top metal layer of the integrated device. The first and second pads 1204 and 1206 are coupled to respective lower metals in the lower metal and dielectric layers 1202.

The redistribution portion 1203 includes a first dielectric layer 1213, a second dielectric layer 1215, a third dielectric layer 1217, a fourth dielectric layer 1219, a first redistribution interconnect 1210, a second redistribution interconnect 1212, a third redistribution interconnect 1214, a fourth redistribution interconnect 1216, a fifth redistribution interconnect 1218, and an under bump metallization (UBM) layer 1220. The first redistribution interconnect 1210 is electrically coupled to the first pad 1204. The second redistribution interconnect 1212 is electrically coupled to the second pad 1206. In some implementations, the first and second redistribution interconnects 1210 and 1212 are on the same redistribution metal layer of the redistribution portion 1203. The third redistribution interconnect 1214 is electrically coupled to the first redistribution interconnect 1210. The fourth redistribution interconnect 1216 is electrically coupled to the second redistribution interconnect 1212. The fifth redistribution interconnect 1218 is electrically coupled to the third redistribution interconnect 1214.

As shown in FIG. 12, a portion of the fourth redistribution interconnect 1216 overlaps (e.g., vertically overlaps) with a portion of the fifth redistribution interconnect 1218. In some implementations, the overlapping (e.g., vertically overlapping) portions of the fourth and fifth redistribution interconnects 1216 and 1218 are configured to form and/or define an electromagnetic (EM) passive device 1230 in the redistribution portion 1203. The EM passive device 1230 may be defined by either or both the redistribution interconnects 1216 and/or 1218. The EM passive device 1230 may include one of at least an inductor, a coupler and/or a transformer. For example, the redistribution interconnects 1216 or 1218 may be configured as an inductor. In another example, the combination of the redistribution interconnects 1216 and 1218 may be configured as a coupler or transformer.

The first, second, third and fourth dielectric layers 1213, 1215, 1217 and 1219 are insulation layers. In some implementations, the first, second, third and fourth dielectric layers 1213, 1215, 1217 and 1219 may be polyimide layers. For example, the first, second, third, and fourth dielectric layers 1213, 1215, 1217, and 1219 may be Polybenzoxazole (PbO) layers and/or polymer layers.

FIG. 12 illustrates that the first dielectric layer 1213 has a first dielectric thickness (t_{d}) and the first redistribution interconnect 1210 has a first redistribution thickness (tᵣ). In some implementations, the first dielectric thickness (t_{d}) is at least about 2 times (2×) greater than the first redistribution thickness (tᵣ). In some implementations, this is done to ensure that the EM passive device 1230 is sufficiently away or offset from components (e.g., active circuits) of the integrated device 1200, and/or to ensure that the EM passive device 1230 does not affect other components of the integrated device 1200. This results in better EM passive device performance in the integrated device 1200. In some implementations, the thickness of other redistribution layers may be similar or about the same as the first redistribution thickness.

The performance of the EM passive device 1230 may further be improved by providing a radio frequency (RF) shield in the integrated device 1200. FIG. 12 illustrates metal layers 1208 (comprising metal layers 1208a, 1208b, 1208c, and 1208d) which are configured to operate as a RF shield in the integrated device 1200. Specifically, the RF shield formed by the metal layers 1208, is located in the redistribution portion 1203 of the integrated device 1200. In some implementations, the RF shield formed by the metal layers 1208 may be at least partially vertically aligned (e.g., partially, substantially, or completely vertically aligned). An example of an RF shield design was previously described in FIG. 6. In some implementations, the RF shield is electrically coupled to an interconnect configured to provide an electrical path for a ground signal. In such instance, the RF shield, comprising the metal layers 1208, is coupled to one or more redistribution interconnects and/or a under bump metallization (UBM) layer.

FIG. 12 further illustrates a solder ball 1220 coupled to the UBM layer 1216. However, in some implementations, the solder ball 1220 may be directly coupled to a redistribution interconnect. For example, the solder ball 1220 may be directly coupled to the fifth redistribution interconnect 1218.

Exemplary Sequence for Providing/Fabricating an Integrated Device that Includes an Electromagnetic (EM) Passive Device and a Radio Frequency (RF) Shield

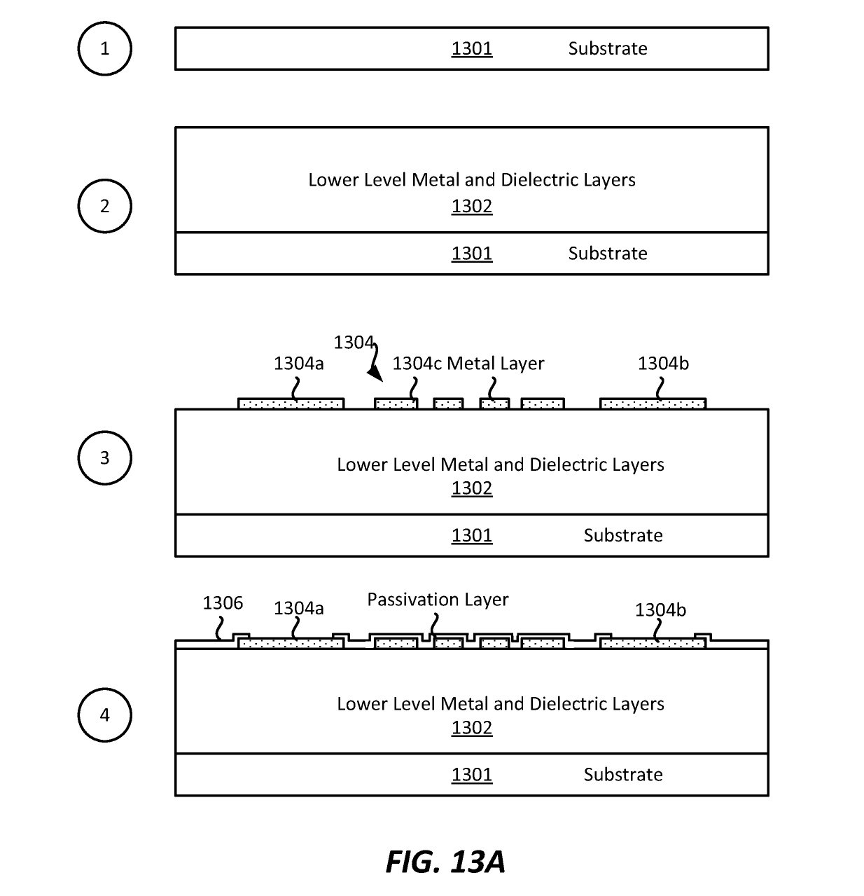

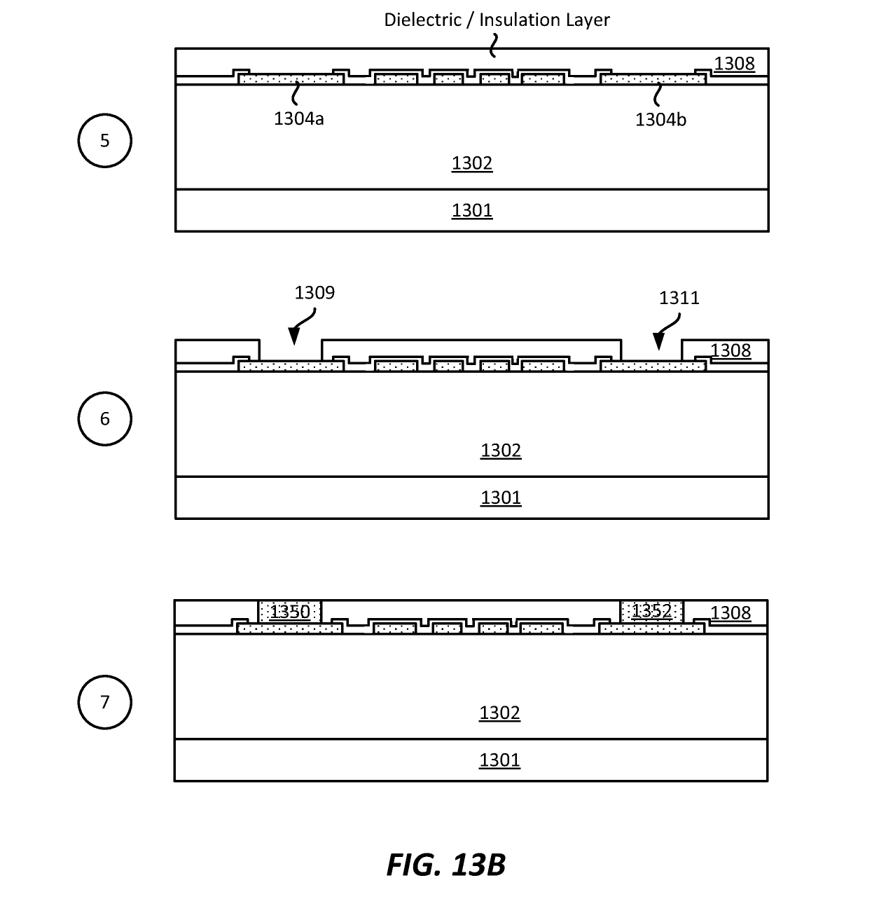

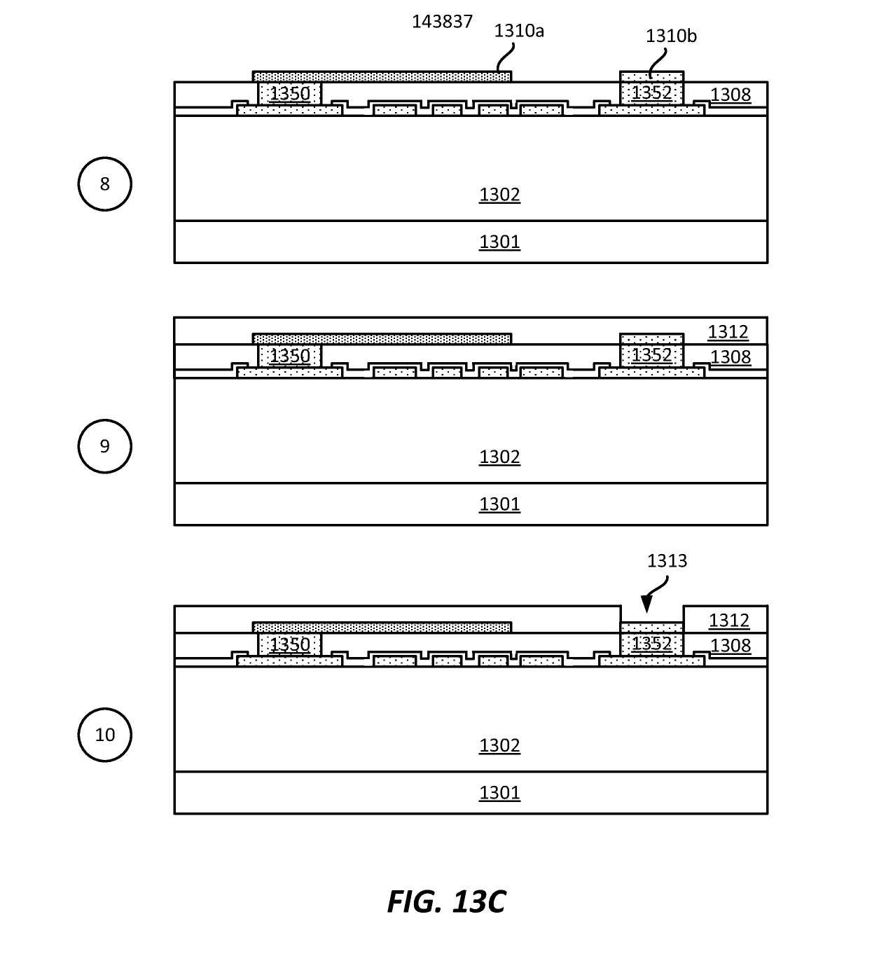

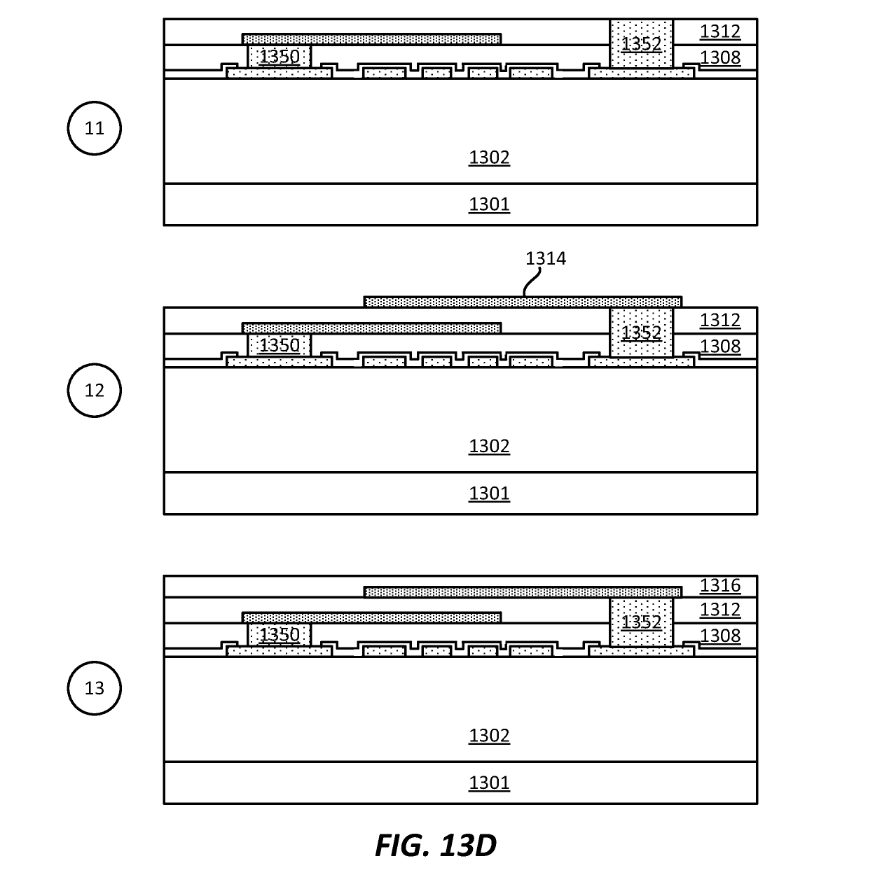

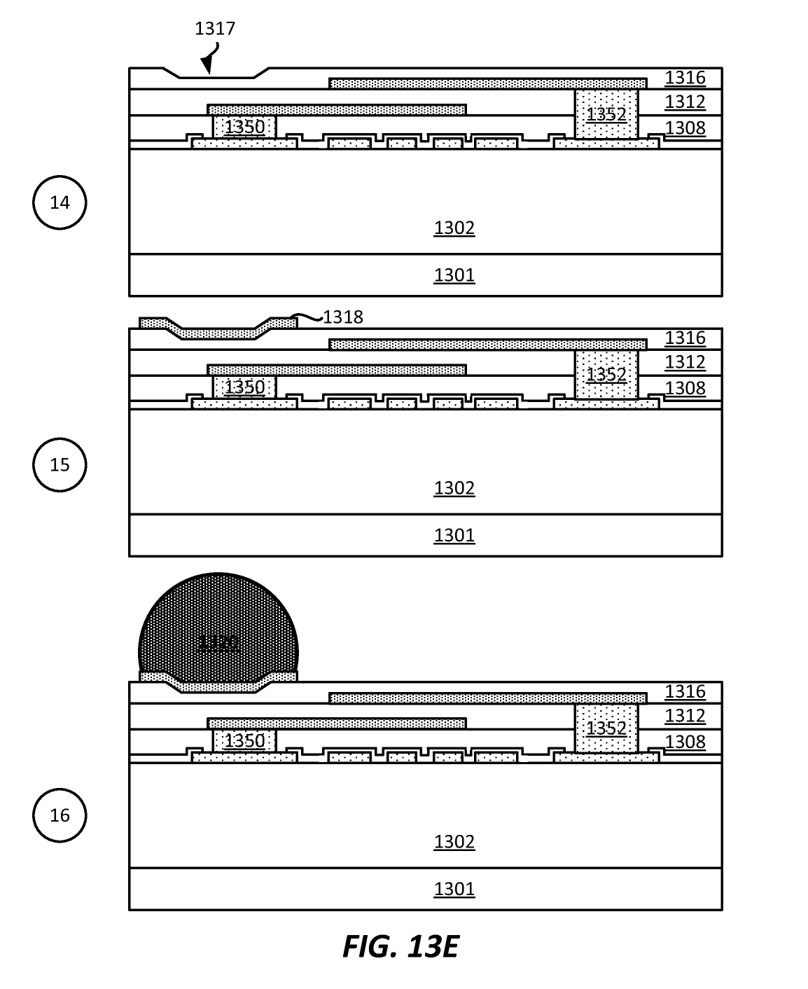

In some implementations, providing/fabricating an integrated device with an electromagnetic (EM) passive device and a radio frequency (RF) shield in a redistribution portion includes several processes. FIG. 13 (which includes FIGS. 13A-13E) illustrates an exemplary sequence for providing/fabricating an integrated device with an EM passive device and a radio frequency (RF) shield in a redistribution portion. In some implementations, the sequence of FIGS. 13A-13E may be used to provide/fabricate the integrated device of FIGS. 4, 7, 8, 9 and/or other integrated device in the present disclosure. However, for the purpose of simplification, FIGS. 13A-13E will be described in the context of providing/fabricating the integrated device of FIG. 4.

It should be noted that the sequence of FIGS. 13A-13E may combine one or more stages in order to simplify and/or clarify the sequence for providing an integrated device. In some implementations, the order of the processes may be changed or modified.

Stage 1 of FIG. 13A, illustrates a state after a substrate 1301 is provided. In some implementations, the substrate 1301 is provided by a supplier. In some implementations, the substrate 1301 is fabricated (e.g., formed). In some implementations, the substrate 1301 is a silicon substrate and/or wafer (e.g., silicon wafer).

Stage 2 illustrates a state after lower level metal and dielectric layers 1302 are provided. In some implementations, providing the lower level metal and dielectric layers 1302 include forming lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 1302 include traces and/or vias. In some implementations, providing the lower level metal and dielectric layers 1302 include forming one or more dielectric layers. In some implementations, the lower level metal and dielectric layers 1302 are provided and/or formed using a back end of line (BEOL) process.

Stage 3 illustrates a state after a first metal layer 1304 is provided (e.g., formed) on the lower level metal and dielectric layers 1302. The first metal layer 1304 may form different components. For example, portions of the first metal layer 1304 may form the first pad 404 and the second pad 406 of FIG. 4. In addition, portions of the first metal layer 1304 may form metal layers 408 (comprising 408a-408d), which is configured to operate as a radio frequency (RF) shield for the integrated device, such as the RF shield described in FIG. 4. At show at stage 3, the first metal layer 1304 forms a first pad 1304a, a second pad 1304b, and portions of a RF shield 1304c.

Stage 4 illustrates a state after a passivation layer 1306 is provided (e.g., formed) over the lower level metal and dielectric layers 1302 and the metal layer 1304. In some implementations, providing the passivation layer 1306 includes forming the passivation layer 1306 on the lower level metal and dielectric layers 1302 and the metal layer 1304 and selectively etching portions of the passivation layer 1306 over the metal layer 1304 (e.g., selectively etching portions of the passivation layer 1306 over of the pads and/or metal layers of a RF shield).

Stage 5, as shown in FIG. 13B, illustrates a state after a first dielectric layer 1308 is provided on the passivation layer 1306 and the metal layer 1304.

Stage 6 illustrates a state after portions of the first dielectric layer 1308 are selectively removed (e.g., etched). As shown at stage 6, portions of the first dielectric layer 1308 are selectively etched to form a cavity 1309 and a cavity 1311 in the first dielectric layer 1308 over the pads.

Stage 7 illustrates a state after a first via 1350 and a second via 1352 are respectively formed in the cavities 1309 and 1311. The first via 1350 is coupled to the pad 1304a, and the second via 1352 is coupled to the pad 1304b.

Stage 8, as shown in FIG. 13C, illustrates a state after a first redistribution layer 1310 is provided (e.g., formed) on the first dielectric layer 1308. As shown at stage 7, the first redistribution layer 1310 includes a first redistribution interconnect 1310a and a second interconnect 1310b. The first redistribution interconnect 1310a is coupled to the first via 1350. The second interconnect 1310b is formed on the second via 1352. In some implementations, the second interconnect 1310b is part of the second via 1352.

In some implementations, the first dielectric layer 1308 has a first dielectric thickness (t_{d}) and the first redistribution layer 1310 has a first redistribution thickness (tᵣ). In some implementations, the first dielectric thickness (t_{d}) is at least about 2 times (2×) greater than the first redistribution thickness (tᵣ).

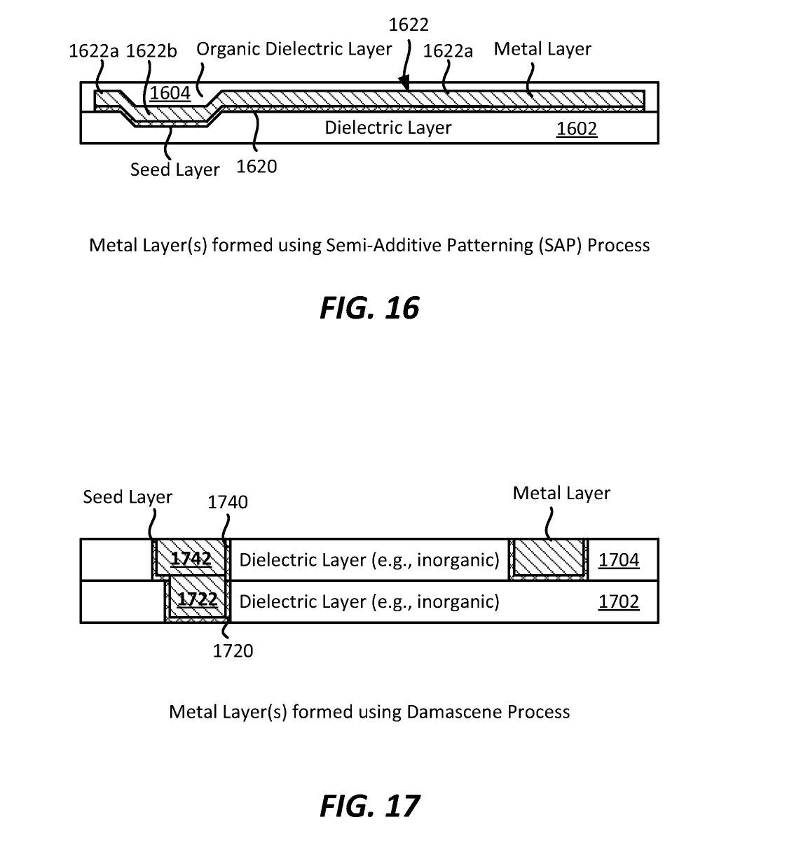

In some implementations, providing the first redistribution layer 1310 includes forming (e.g., plating) one or more metal layers (e.g., seed layer and metal layer) and selectively etching portions of the one or more metal layers. FIGS. 16-21 illustrate examples of providing one or more metal layers using several plating processes.

Stage 9 illustrates a state after a second dielectric layer 1312 is provided on the first dielectric layer 1308 and the first redistribution layer 1310.

Stage 10 illustrates a state after portions of the second dielectric layer 1312 are selectively removed (e.g., etched). As shown at stage 10, portions of the second dielectric layer 1312 are selectively etched to form a cavity 1313 in the second dielectric layer 1312 over the second interconnect 1310b and/or the second via 1352.

Stage 11, as shown in FIG. 13D, illustrates a state after a metal layer is formed in the cavity 1313 to further form and/or define the second via 1352.

Stage 12 illustrates a state after a second redistribution layer 1314 is provided (e.g., formed) on the second dielectric layer 1312. The second redistribution layer 1314 is coupled to the second interconnect 1310b. FIGS. 16-21 illustrate examples of providing one or more metal layers (e.g., redistribution layer) using several plating processes.

Stage 13 illustrates a state after a third dielectric layer 1316 is provided on the second dielectric layer 1312 and the second redistribution layer 1312.

Stage 14, as shown in FIG. 13E, illustrates a state after portions of the third dielectric layer 1316 are selectively removed (e.g., etched). As shown at stage 12, portions of the third dielectric layer 1316 are selectively etched to form a cavity 1317 in the third dielectric layer 1316.

Stage 15 illustrates a state after an under bump metallization (UBM) layer 1318 is provided (e.g., formed) on the third dielectric layer 1316 and the second redistribution layer 1314. In some implementations, the UBM layer 1318 is optional. FIGS. 16-21 illustrate examples of providing one or more metal layers (e.g., UBM layer) using several plating processes.

Stage 16 illustrates a state after a solder ball 1320 is provided (e.g., coupled) to the UBM layer 1318. In some implementations, the UBM layer 1318 is optional. In such instances, the solder ball 1320 may be directly coupled to the second redistribution layer 1314.

Exemplary Sequence for Providing/Fabricating an Integrated Device that Includes an Electromagnetic (EM) Passive Device and a Radio Frequency (RF) Shield

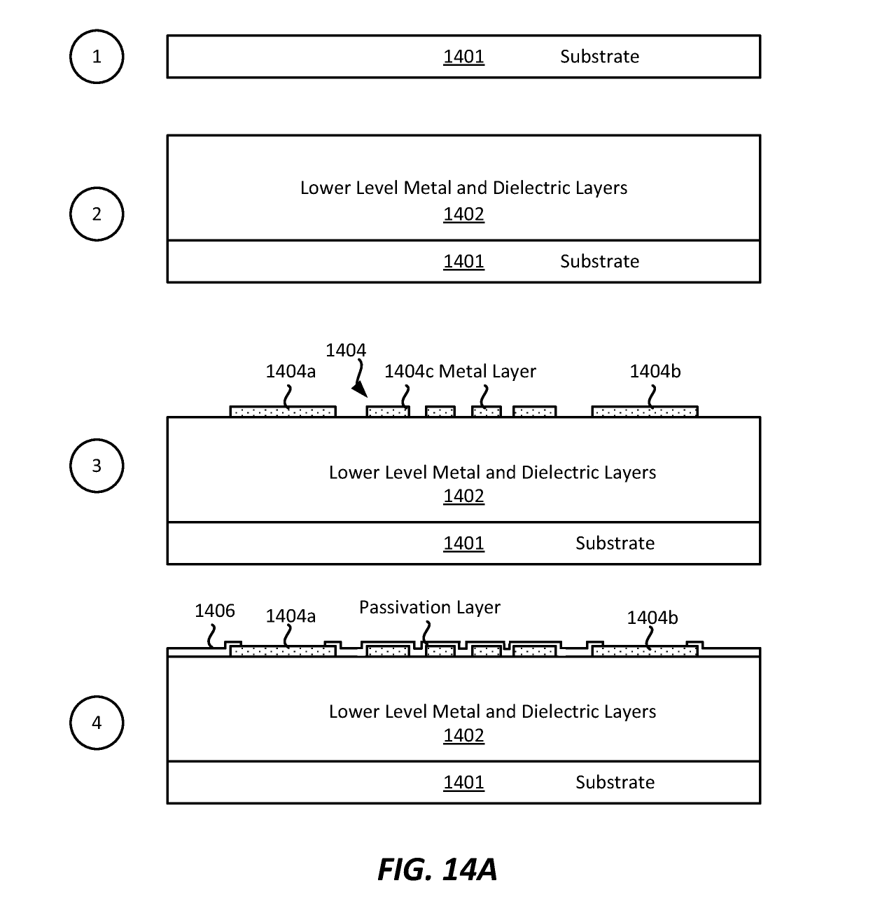

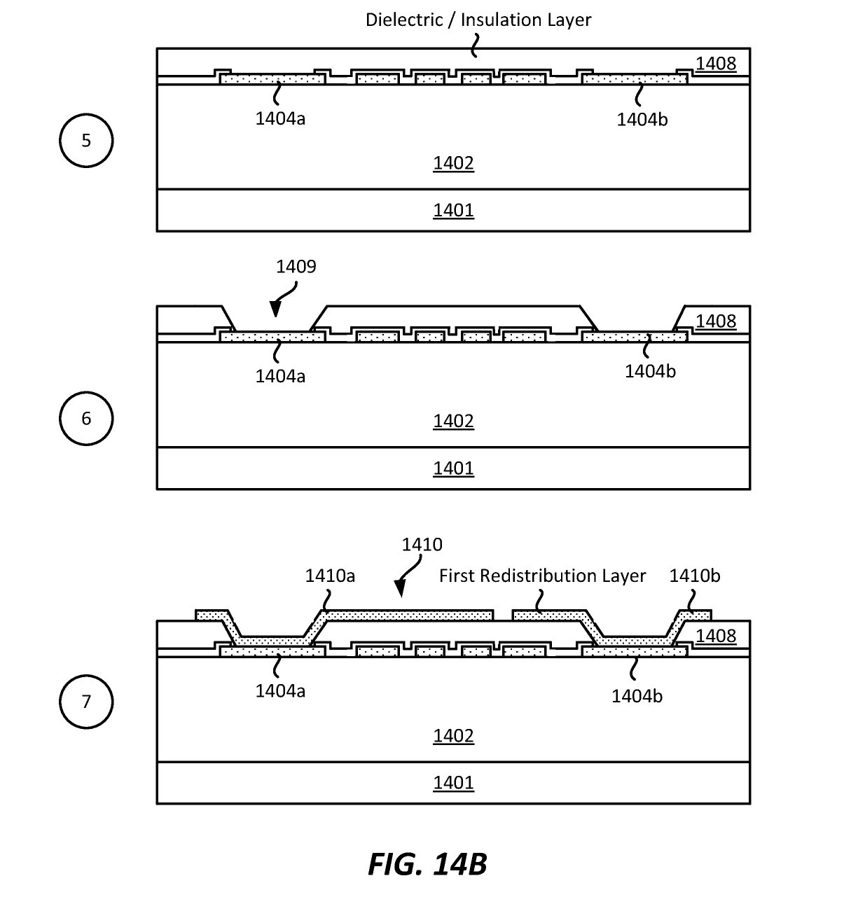

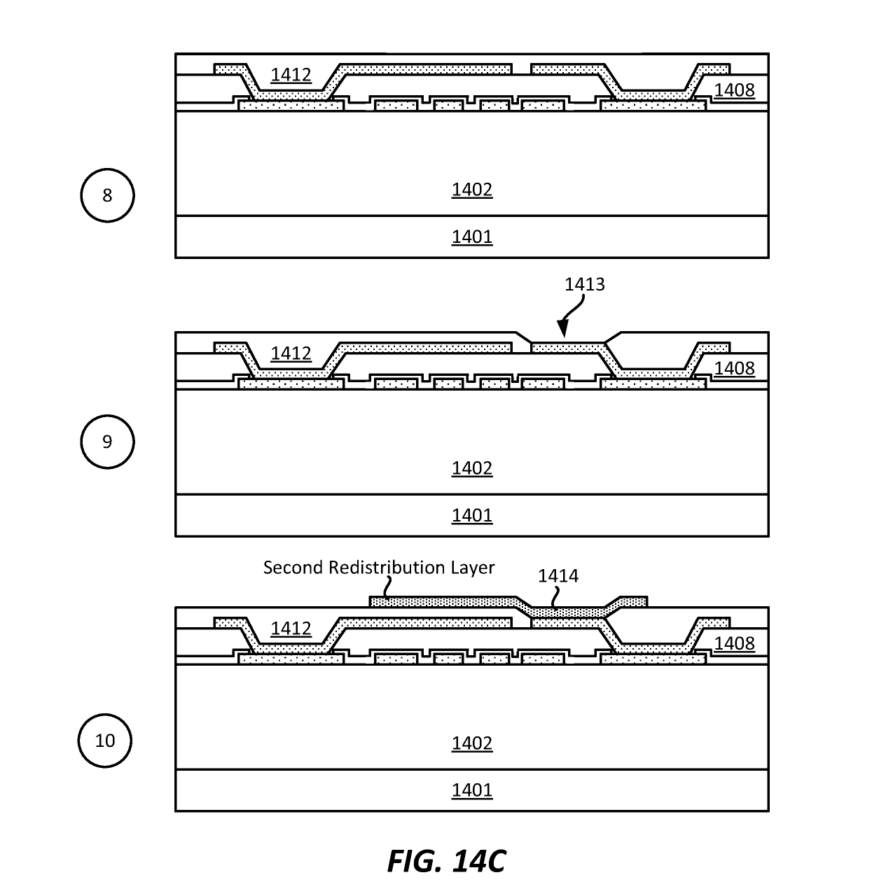

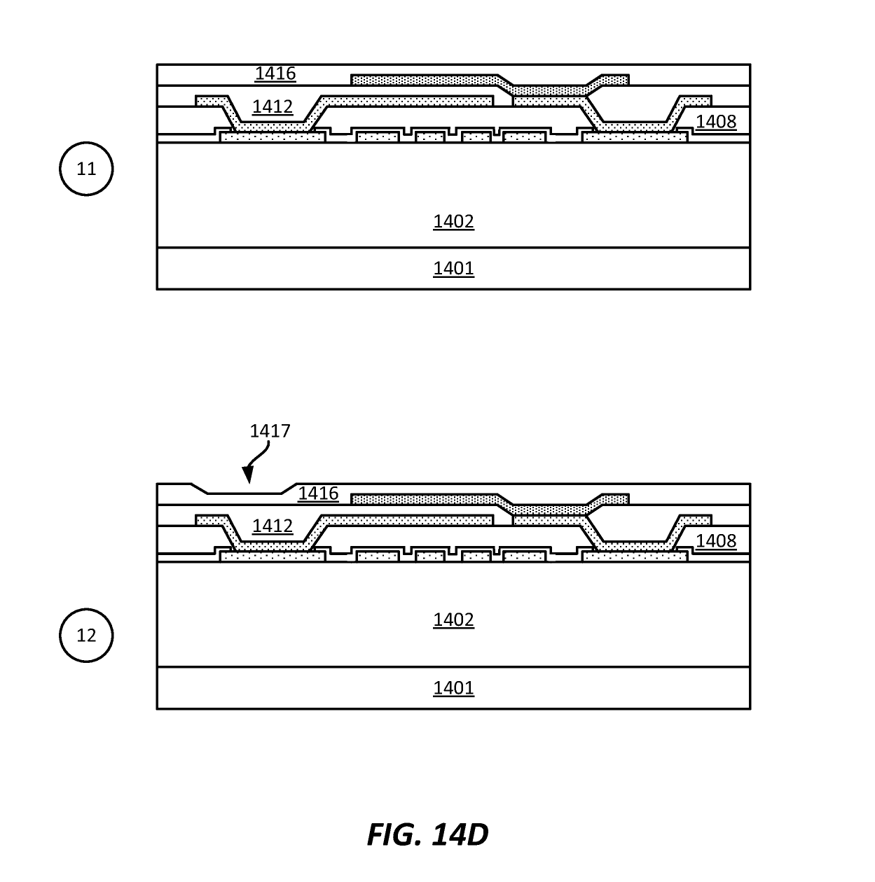

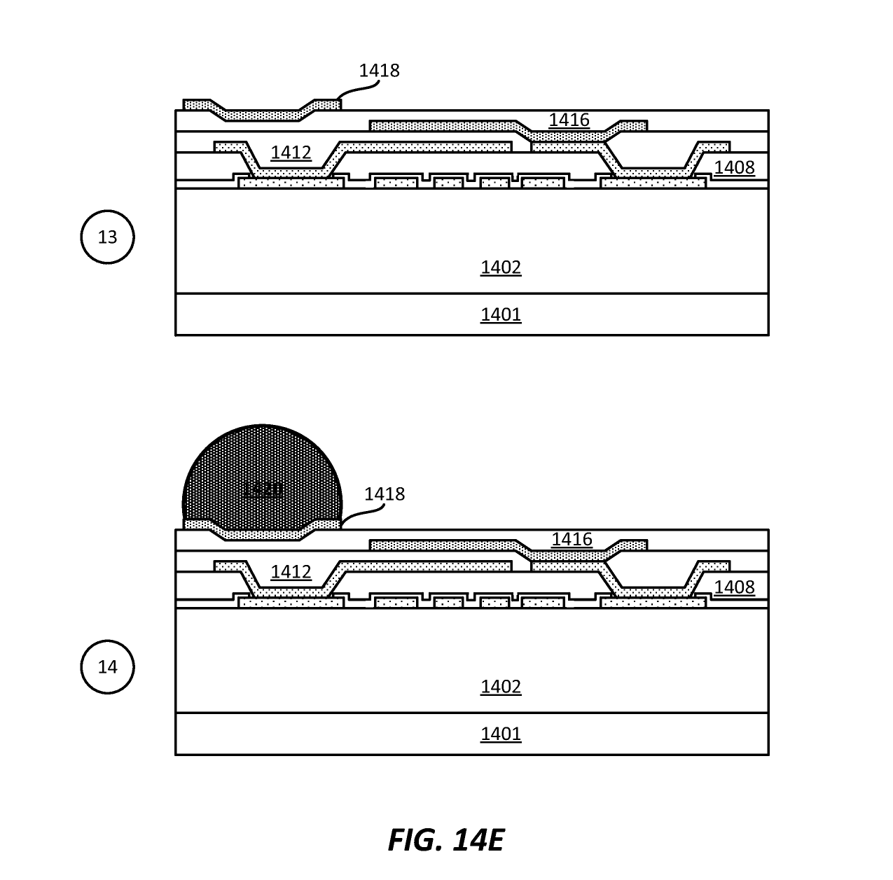

In some implementations, providing/fabricating an integrated device with an electromagnetic (EM) passive device and a radio frequency (RF) shield in a redistribution portion includes several processes. FIG. 14 (which includes FIGS. 14A-14E) illustrates an exemplary sequence for providing/fabricating an integrated device with an EM passive device and a radio frequency (RF) shield in a redistribution portion. In some implementations, the sequence of FIGS. 14A-14E may be used to provide/fabricate the integrated device of FIGS. 10, 11, 12 and/or other integrated device in the present disclosure. However, for the purpose of simplification, FIGS. 14A-14E will be described in the context of providing/fabricating the integrated device of FIG. 11.

It should be noted that the sequence of FIGS. 14A-14E may combine one or more stages in order to simplify and/or clarify the sequence for providing an integrated device. In some implementations, the order of the processes may be changed or modified.

Stage 1 of FIG. 14A, illustrates a state after a substrate 1401 is provided. In some implementations, the substrate 1401 is provided by a supplier. In some implementations, the substrate 1401 is fabricated (e.g., formed). In some implementations, the substrate 1401 is a silicon substrate and/or wafer (e.g., silicon wafer).

Stage 2 illustrates a state after lower level metal and dielectric layers 1402 are provided. In some implementations, providing the lower level metal and dielectric layers 1402 include forming lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 1402 include traces and/or vias. In some implementations, providing the lower level metal and dielectric layers 1402 include forming one or more dielectric layers. In some implementations, the lower level metal and dielectric layers 1402 are provided and/or formed using a back end of line (BEOL) process.

Stage 3 illustrates a state after a first metal layer 1404 is provided (e.g., formed) on the lower level metal and dielectric layers 1402. The first metal layer 1404 may form different components. For example, portions of the first metal layer 1404 may form the first pad 1104 and the second pad 1106 of FIG. 11. In addition, portions of the first metal layer 1404 may form metal layers 1108 (comprising 1108a-1108d), which is configured to operate as a radio frequency (RF) shield for the integrated device, such as the RF shield described in FIG. 11. At show at stage 3, the first metal layer 1404 forms a first pad 1404a, a second pad 1404b, and portions of a RF shield 1404c.

Stage 4 illustrates a state after a passivation layer 1406 is provided (e.g., formed) over the lower level metal and dielectric layers 1402 and the metal layer 1404. In some implementations, providing the passivation layer 1406 includes forming the passivation layer 1406 on the lower level metal and dielectric layers 1402 and the metal layer 1404 and selectively etching portions of the passivation layer 1406 over the metal layer 1404 (e.g., selectively etching portions of the passivation layer 1406 over of the pads and/or metal layers of a RF shield).

Stage 5, as shown in FIG. 14B, illustrates a state after a first dielectric layer 1408 is provided on the passivation layer 1406 and the metal layer 1404.

Stage 6 illustrates a state after portions of the first dielectric layer 1408 are selectively removed (e.g., etched). As shown at stage 6, portions of the first dielectric layer 1408 over the pads are selectively etched to form a cavity 1409 in the first dielectric layer 1408 over the pads.

Stage 7 illustrates a state after a first redistribution layer 1410 is provided (e.g., formed) on the first dielectric layer 1408. As shown at stage 7, the first redistribution layer 1410 includes a first redistribution interconnect 1410a and a second redistribution interconnect 1410b. The first redistribution interconnect 1410a is coupled to the first pad 1404a and the second redistribution interconnect 1410b is coupled to a second pad 1404b.

In some implementations, the first dielectric layer 1408 has a first dielectric thickness (t_{d}) and the first redistribution layer 1410 has a first redistribution thickness (tᵣ). In some implementations, the first dielectric thickness (t_{d}) is at least about 2 times (2×) greater than the first redistribution thickness (tᵣ).

In some implementations, providing the first redistribution layer 1410 includes forming (e.g., plating) one or more metal layers (e.g., seed layer and metal layer) and selectively etching portions of the one or more metal layers. FIGS. 16-21 illustrate examples of providing one or more metal layers using several plating processes.

Stage 8, as shown in FIG. 14C, illustrates a state after a second dielectric layer 1412 is provided on the first dielectric layer 1408 and the first redistribution layer 1410.

Stage 9 illustrates a state after portions of the second dielectric layer 1412 are selectively removed (e.g., etched). As shown at stage 9, portions of the second dielectric layer 1412 over portions of the second redistribution interconnect 1410b are selectively etched to form a cavity 1413 in the second dielectric layer 1412 over the second redistribution interconnect 1410b.

Stage 10 illustrates a state after a second redistribution layer 1414 is provided (e.g., formed) on the second dielectric layer 1412. The second redistribution layer 1414 is a third redistribution interconnect. The second redistribution layer 1414 is coupled to the second interconnect 1410b. FIGS. 16-21 illustrate examples of providing one or more metal layers (e.g., redistribution layer) using several plating processes.

Stage 11, as shown in FIG. 14D, illustrates a state after a third dielectric layer 1416 is provided on the second dielectric layer 1412 and the second redistribution layer 1412.

Stage 12 illustrates a state after portions of the third dielectric layer 1416 are selectively removed (e.g., etched). As shown at stage 12, portions of the third dielectric layer 1416 are selectively etched to form a cavity 1417 in the third dielectric layer 1416.

Stage 13, as shown in FIG. 14E, illustrates a state after an under bump metallization (UBM) layer 1418 is provided (e.g., formed) on the third dielectric layer 1416 and the second redistribution layer 1414. In some implementations, the UBM layer 1418 is optional. FIGS. 16-21 illustrate examples of providing one or more metal layers (e.g., UBM layer) using several plating processes.

Stage 14 illustrates a state after a solder ball 1420 is provided (e.g., coupled) to the UBM layer 1418. In some implementations, the UBM layer 1418 is optional. In such instances, the solder ball 1420 may be directly coupled to the second redistribution layer 1414.

Exemplary Flow Diagram of a Method for Providing/Fabricating an Integrated Device that Includes an Electromagnetic (EM) Passive Device and a Radio Frequency (RF) Shield

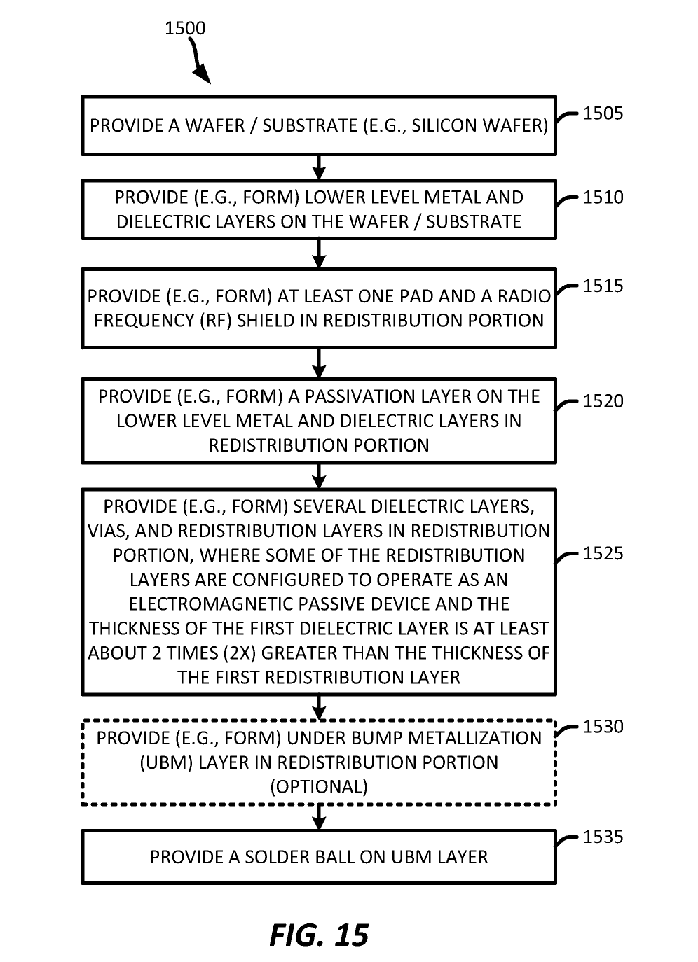

In some implementations, providing/fabricating an integrated device with an electromagnetic (EM) passive device and a radio frequency (RF) shield in a redistribution portion includes several processes. FIG. 15 illustrates an exemplary flow diagram of a method for providing/fabricating an integrated device with an EM passive device and a radio frequency (RF) shield in a redistribution portion.

In some implementations, the method of FIG. 15 may be used to provide/fabricate the substrate of FIGS. 4, 7, 8, 9, 10, 11, 12, and/or other integrated devices in the present disclosure. It should be noted that the method of FIG. 15 may combine one or more steps in order to simplify and/or clarify the method for providing an integrated device. In some implementations, the order of the processes may be changed or modified.

The method provides (at 1505) a substrate. In some implementations, the substrate is provided by a supplier. In some implementations, providing the substrate includes fabricating the substrate. In some implementations, the substrate is a silicon substrate and/or wafer (e.g., silicon wafer).

The method provides (at 1510) lower level metal and dielectric layers. In some implementations, providing the lower level metal and dielectric layers include forming lower level metal layers (e.g., M1 metal layer, M2 metal layer, M3 metal layer, M4 metal layer, M5 metal layer, M6 metal layer, M7 metal layer). The lower metal layers of the lower level metal and dielectric layers 1402 include traces and/or vias. In some implementations, providing the lower level metal and dielectric layers 1402 include forming one or more dielectric layers. In some implementations, the lower level metal and dielectric layers 1402 are provided and/or formed using a back end of line (BEOL) process.

The method provides (at 1515) a set of a pads and at least one radio frequency (RF) shield. The set of pads and the RF shield may be formed over the lower level metal and dielectric layers. In some implementations, providing (e.g., forming) the RF shield is optional.

The method provides (at 1520) a passivation layer over the set of pads, the RF shield and the lower level metal and dielectric layers. In some implementations, providing (at 1520) the passivation layer includes forming the passivation layer on the lower level metal and dielectric layers and the metal layer (e.g., pads, RF shield) and selectively etching portions of the passivation layer over the metal layer (e.g., selectively etching portions of the passivation layer over of the pads and/or metal layers of a RF shield).

The method then provides (at 1525) several dielectric layers and several redistribution metal layers, where at least some of the redistribution layers are configured to operate as an electromagnetic (EM) passive device. In some implementations, a first dielectric layer has a first dielectric thickness (t_{d}) and a first redistribution layer has a first redistribution thickness (tᵣ). In some implementations, the first dielectric thickness (t_{d}) is at least about 2 times (2×) greater than the first redistribution thickness (tᵣ). Stages 5-11 of FIGS. 14B-14D illustrate an example of providing/forming dielectric layers and redistribution layers, where some of the redistribution layers are configured to operate as an EM passive device in a redistribution portion of an integrated device.

The method optionally provides (at 1530) an under bump metallization (UBM) layer. In some implementations, providing the UBM layer includes forming the UBM layer such that the UBM layer is coupled to one of the redistribution layer.

The method then provides (at 1535) a solder ball on the UBM layer. In some implementations, the UBM layer is optional. In such instances, the solder ball may be directly coupled to a redistribution layer.

Exemplary Interconnects with Seed Layers

Various interconnects (e.g., traces, vias, pads) are described in the present disclosure. These interconnects may be formed in the substrate and/or the redistribution portion. In some implementations, these interconnects may includes one or more metal layers. For example, in some implementations, these interconnects may include a first metal seed layer and a second metal layer. The metal layers may be provided (e.g., formed) using different plating processes. Below are detailed examples of interconnects (e.g., traces, vias, pads) with seed layers and how these interconnects may be formed using different plating processes.

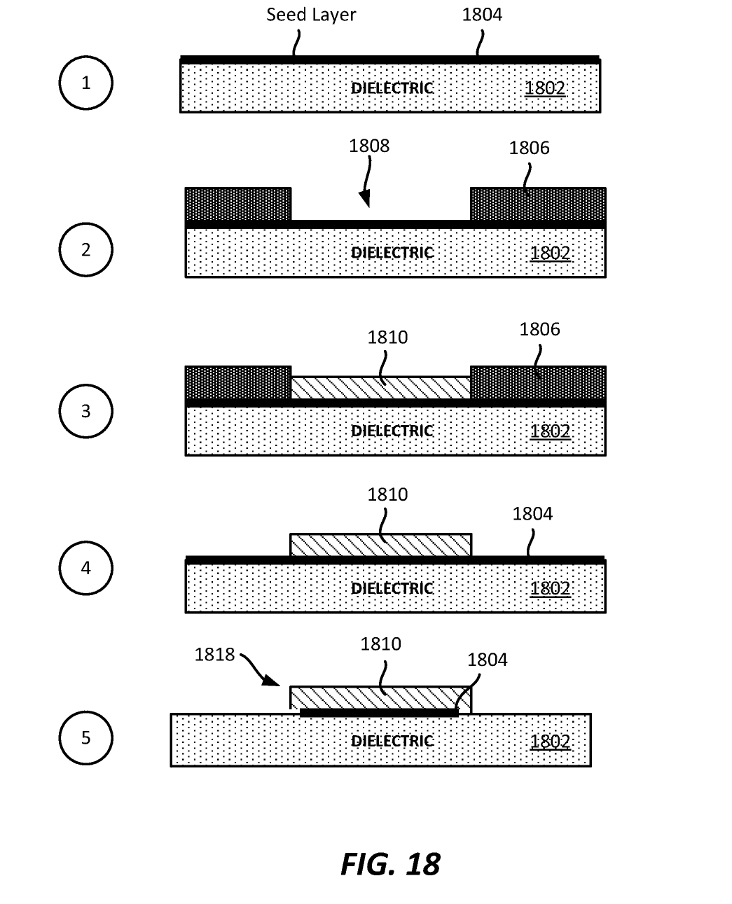

FIG. 16 illustrates a detailed profile view of a metal layer formed using a semi-additive patterning (SAP) process. Specifically, FIG. 16 illustrates a first dielectric layer 1602, a second organic dielectric layer 1604, a first seed layer 1620, and a second metal layer 1622. The first seed layer 1620 is a metal layer (e.g., TiCu, TiWCu). In some implementations, the first seed layer 1620 is formed by a first deposition process (e.g., physical vapor deposition (PVD) or plating process). The second metal layer 1622 is formed by a second deposition process (e.g., plating process). The second metal layer 1622 includes a first metal portion layer 1622a and a second metal portion layer 1622b. In some implementations, the first metal portion layer 1622a is a metal trace. In some implementations, the second metal portion 1622b is a via/via structure. As shown in FIG. 16, the first seed layer 1620 is formed in a base portion of the second metal layer 1622. FIG. 16 illustrates that the first seed layer 1620 is not formed in the side planar portion of the second metal layer 1622. More specifically, FIG. 16 illustrates that the first seed layer 1620 is formed on the base portion (e.g., bottom portion) of the second metal layer 1622, but not on the boundary side portions of the second metal layer 1622. As described above, the second metal layer 1622 includes a first metal portion layer 1622a and a second metal portion layer 1622b. The first seed layer 1620 is formed on the base portion of both the first metal portion layer 1622a and the second metal portion layer 1622b. The first seed layer 1620 is formed on the side portion/wall of the second metal portion layer 1622b (e.g., side portion/wall of the via/via structure), but not on the side portion/wall/boundary of the first metal portion layer 1622a. The metal layers may be formed using a semi-additive patterning (SAP) process. As mentioned above, FIGS. 18-21 illustrate an example of a semi-additive patterning (SAP) process in some implementations.

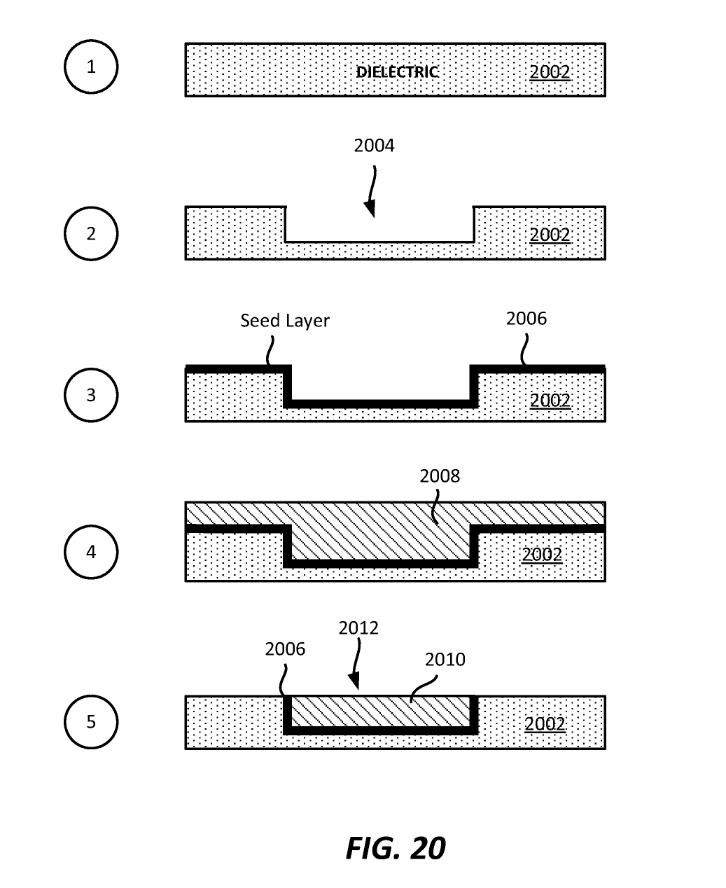

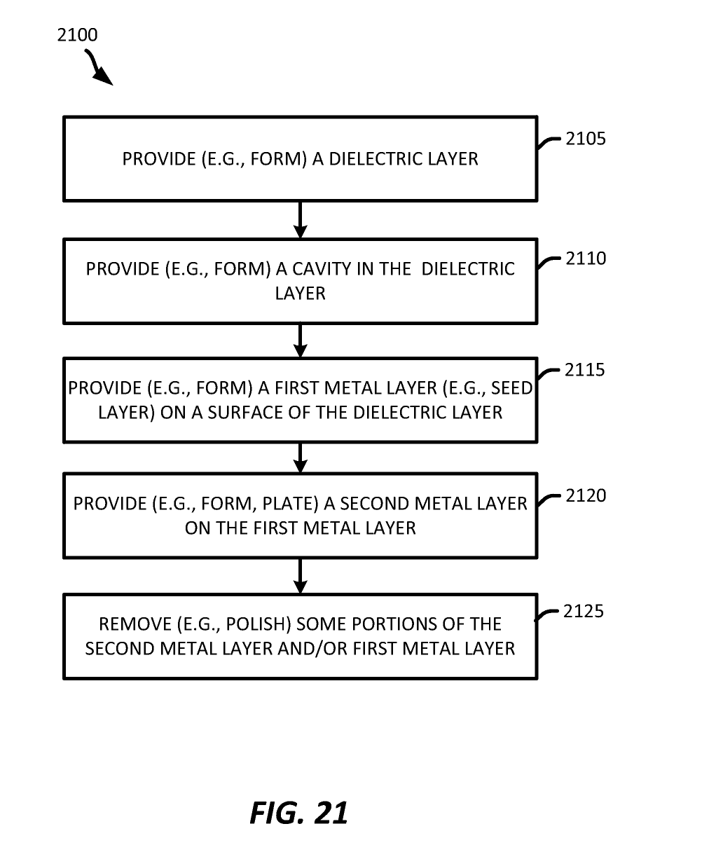

FIG. 17 illustrates a detailed profile view of a metal layer formed using a damascene process. Specifically, FIG. 17 illustrates a first dielectric layer 1702 (e.g., inorganic dielectrics, polymer), a second dielectric layer 1704 (e.g., inorganic dielectrics, polymer), a first seed layer 1720, a second metal layer 1722, a third seed layer 1740, and a fourth metal layer 1742. The first seed layer 1720 and/or the third seed layer 1740 are metal layers (e.g., TiTiN/Cu, TaTaN/Cu). In some implementations, the first seed layer 1720 and/or the third seed layer 1740 are formed by a first deposition process (e.g., chemical vapor deposition (CVP) or physical vapor deposition (PVD)). The second metal layer 1722 and/or the fourth metal layer 1742 are formed by a second deposition process (e.g., plating process). As shown in FIG. 17, the first seed layer 1720 is formed in a base horizontal planar portion and a side planar portion (e.g., vertical planar portion) of the second metal layer 1722. Similarly, the third seed layer 1740 is formed in a base horizontal planar portion and a side planar portions (e.g., vertical planar portions) of the fourth metal layer 1742. As mentioned above, FIGS. 20-21 illustrate an example of a damascene process in some implementations.

### Exemplary Semi-Additive Patterning (SAP) Process

FIG. 18 illustrates a sequence for forming an interconnect using a semi-additive patterning (SAP) process to provide and/or form an interconnect in one or more dielectric layer(s). As shown in FIG. 18, stage 1 illustrates a state of an integrated device (e.g., substrate) after a dielectric layer 1802 is provided (e.g., formed). In some implementations, stage 1 illustrates that the dielectric layer 1802 includes a first metal layer 1804. The first metal layer 1804 is a seed layer in some implementations. In some implementations, the first metal layer 1804 may be provided (e.g., formed) on the dielectric layer 1802 after the dielectric layer 1802 is provided (e.g., received or formed). Stage 1 illustrates that the first metal layer 1804 is provided (e.g., formed) on a first surface of the dielectric layer 1802. In some implementations, the first metal layer 1804 is provided by using a deposition process (e.g., PVD, CVD, plating process).

Stage 2 illustrates a state of the integrated device after a photo resist layer 1806 (e.g., photo develop resist layer) is selectively provided (e.g., formed) on the first metal layer 1804. In some implementations, selectively providing the resist layer 1806 includes providing a first resist layer 1806 on the first metal layer 1804 and selectively removing portions of the resist layer 1806 by developing (e.g., using a development process). Stage 2 illustrates that the resist layer 1806 is provided such that a cavity 1808 is formed.

Stage 3 illustrates a state of the integrated device after a second metal layer 1810 is formed in the cavity 1808. In some implementations, the second metal layer 1810 is formed over an exposed portion of the first metal layer 1804. In some implementations, the second metal layer 1810 is provided by using a deposition process (e.g., plating process).

Stage 4 illustrates a state of the integrated device after the resist layer 1806 is removed. Different implementations may use different processes for removing the resist layer 1806.

Stage 5 illustrates a state of the integrated device after portions of the first metal layer 1804 are selectively removed. In some implementations, one or more portions of the first metal layer 1804 that is not covered by the second metal layer 1806 is removed. As shown in stage 5, the remaining first metal layer 1802 and the second metal layer 1810 may form and/or define an interconnect 1812 (e.g., trace, vias, pads) in an integrated device and/or a substrate. In some implementations, the first metal layer 1806 is removed such that a dimension (e.g., length, width) of the first metal layer 1806 underneath the second metal layer 1810 is smaller than a dimension (e.g., length, width) of the second metal layer 1810, which can result in an undercut, as shown at stage 5 of FIG. 18. In some implementations, the above mentioned processes may be iterated several times to provide and/or form several interconnects in one or more dielectric layers of an integrated device and/or substrate.

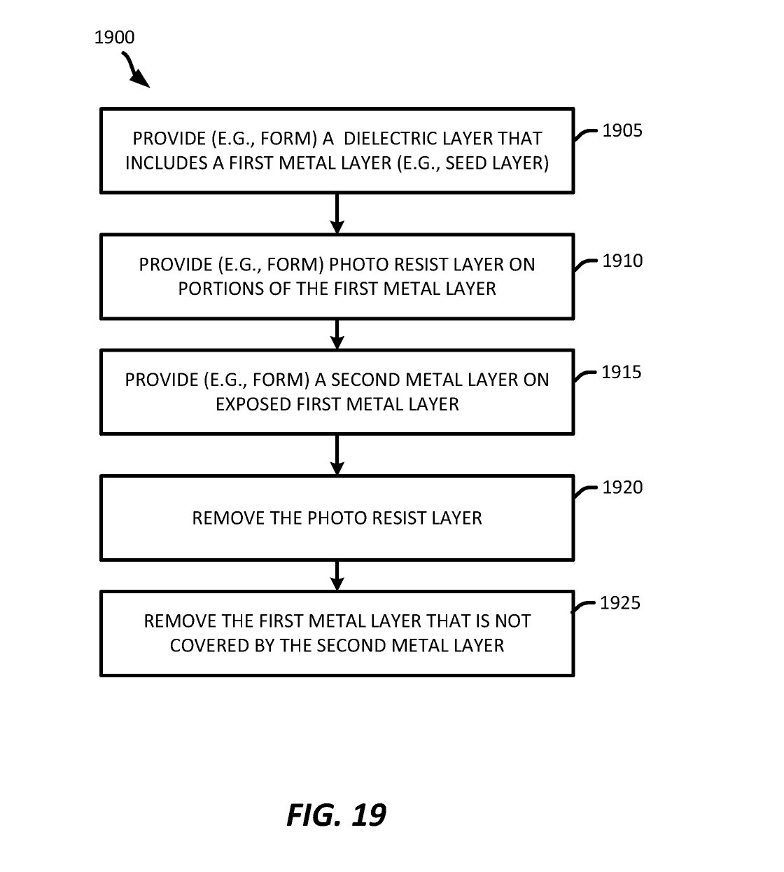

FIG. 19 illustrates a flow diagram for a method for using a (SAP) process to provide and/or form an interconnect in one or more dielectric layer(s). The method provides (at 1905) a dielectric layer (e.g., dielectric layer 1802). In some implementations, providing the dielectric layer includes forming the dielectric layer. In some implementations, providing the dielectric layer includes forming a first metal layer (e.g., first metal layer 1804). The first metal layer is a seed layer in some implementations. In some implementations, the first metal layer may be provided (e.g., formed) on the dielectric layer after the dielectric layer is provided (e.g., received or formed). In some implementations, the first metal layer is provided by using a deposition process (e.g., physical vapor deposition (PVD) or plating process).

The method selectively provides (at 1910) a photo resist layer (e.g., a photo develop resist layer 1806) on the first metal layer. In some implementations, selectively providing the resist layer includes providing a first resist layer on the first metal layer and selectively removing portions of the resist layer (which provides one or more cavities).

The method then provides (at 1915) a second metal layer (e.g., second metal layer 1810) in the cavity of the photo resist layer. In some implementations, the second metal layer is formed over an exposed portion of the first metal layer. In some implementations, the second metal layer is provided by using a deposition process (e.g., plating process).

The method further removes (at 1920) the resist layer. Different implementations may use different processes for removing the resist layer. The method also selectively removes (at 1925) portions of the first metal layer. In some implementations, one or more portions of the first metal layer that is not covered by the second metal layer are removed. In some implementations, any remaining first metal layer and second metal layer may form and/or define one or more interconnects (e.g., trace, vias, pads) in an integrated device and/or a substrate. In some implementations, the above mentioned method may be iterated several times to provide and/or form several interconnects in one or more dielectric layers of an integrated device and/or substrate.

### Exemplary Damascene Process

FIG. 20 illustrates a sequence for forming an interconnect using a damascene process to provide and/or form an interconnect in a dielectric layer. As shown in FIG. 20, stage 1 illustrates a state of an integrated device after a dielectric layer 2002 is provided (e.g., formed). In some implementations, the dielectric layer 2002 is an inorganic layer (e.g., inorganic film).

Stage 2 illustrates a state of an integrated device after a cavity 2004 is formed in the dielectric layer 2002. Different implementations may use different processes for providing the cavity 2004 in the dielectric layer 2002.

Stage 3 illustrates a state of an integrated device after a first metal layer 2006 is provided on the dielectric layer 2002. As shown in stage 3, the first metal layer 2006 provided on a first surface of the dielectric later 2002. The first metal layer 2006 is provided on the dielectric layer 2002 such that the first metal layer 2006 takes the contour of the dielectric layer 2002 including the contour of the cavity 2004. The first metal layer 2006 is a seed layer in some implementations. In some implementations, the first metal layer 2006 is provided by using a deposition process (e.g., physical vapor deposition (PVD), Chemical Vapor Deposition (CVP) or plating process).

Stage 4 illustrates a state of the integrated device after a second metal layer 2008 is formed in the cavity 2004 and a surface of the dielectric layer 2002. In some implementations, the second metal layer 2008 is formed over an exposed portion of the first metal layer 2006. In some implementations, the second metal layer 2008 is provided by using a deposition process (e.g., plating process).

Stage 5 illustrates a state of the integrated device after the portions of the second metal layer 2008 and portions of the first metal layer 2006 are removed. Different implementations may use different processes for removing the second metal layer 2008 and the first metal layer 2006. In some implementations, a chemical mechanical planarization (CMP) process is used to remove portions of the second metal layer 2008 and portions of the first metal layer 2006. As shown in stage 5, the remaining first metal layer 2006 and the second metal layer 2008 may form and/or define an interconnect 2012 (e.g., trace, vias, pads) in an integrated device and/or a substrate. As shown in stage 5, the interconnect 2012 is formed in such a way that the first metal layer 2006 is formed on the base portion and the side portion(s) of the second metal layer 2010. In some implementations, the cavity 2004 may include a combination of trenches and/or holes in two levels of dielectrics so that via and interconnects (e.g., metal traces) may be formed in a single deposition step, In some implementations, the above mentioned processes may be iterated several times to provide and/or form several interconnects in one or more dielectric layers of an integrated device and/or substrate.

FIG. 21 illustrates a flow diagram of a method for forming an interconnect using a damascene process to provide and/or form an interconnect in a dielectric layer. The method provides (at 2105) a dielectric layer (e.g., dielectric layer 2002). In some implementations, providing a dielectric layer includes forming a dielectric layer. In some implementations, providing a dielectric layer includes receiving a dielectric layer from a supplier. In some implementations, the dielectric layer is an inorganic layer (e.g., inorganic film).

The method forms (at 2110) at least one cavity (e.g., cavity 2004) in the dielectric layer. Different implementations may use different processes for providing the cavity in the dielectric layer.

The method provides (at 2115) a first metal layer (e.g., first metal layer 2006) on the dielectric layer. In some implementations, the first metal layer is provided (e.g., formed) on a first surface of the dielectric later. In some implementations, the first metal layer is provided on the dielectric layer such that the first metal layer takes the contour of the dielectric layer including the contour of the cavity. The first metal layer is a seed layer in some implementations. In some implementations, the first metal layer 2006 is provided by using a deposition process (e.g., PVD, CVD or plating process).

The method provides (at 2120) a second metal layer (e.g., second metal layer 2008) in the cavity and a surface of the dielectric layer. In some implementations, the second metal layer is formed over an exposed portion of the first metal layer. In some implementations, the second metal layer is provided by using a deposition process (e.g., plating process). In some implementations, the second metal layer is similar or identical to the first metal layer. In some implementations, the second metal layer is different than the first metal layer.

The method then removes (at 2125) portions of the second metal layer and portions of the first metal layer. Different implementations may use different processes for removing the second metal layer and the first metal layer. In some implementations, a chemical mechanical planarization (CMP) process is used to remove portions of the second metal layer and portions of the first metal layer. In some implementations, the remaining first metal layer and the second metal layer may form and/or define an interconnect (e.g., interconnect 2012). In some implementations, an interconnect may include one of at least a trace, a via, and/or a pad) in an integrated device and/or a substrate. In some implementations, the interconnect is formed in such a way that the first metal layer is formed on the base portion and the side portion(s) of the second metal layer. In some implementations, the above mentioned method may be iterated several times to provide and/or form several interconnects in one or more dielectric layers of an integrated device and/or substrate.

### Exemplary Electronic Devices

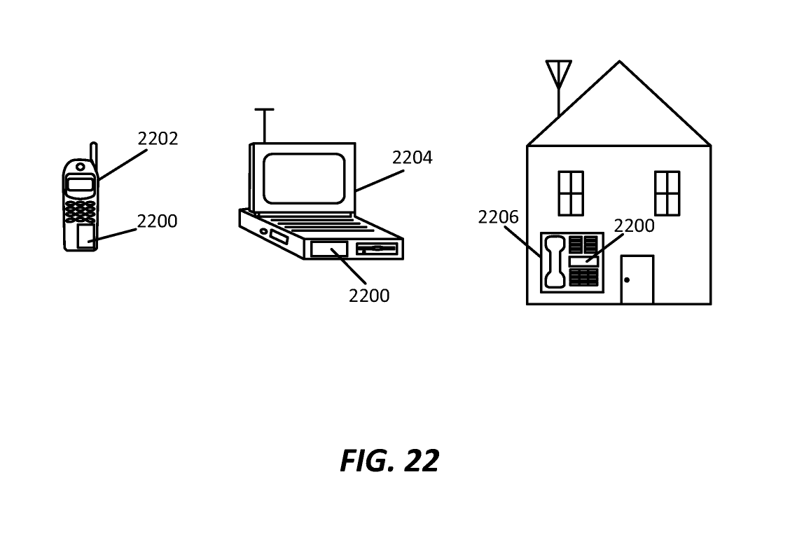

FIG. 22 illustrates various electronic devices that may be integrated with any of the aforementioned integrated device, semiconductor device, integrated circuit, die, interposer, package or package-on-package (PoP). For example, a mobile telephone 2202, a laptop computer 2204, and a fixed location terminal 2206 may include an integrated device 2200 as described herein. The integrated device 2200 may be, for example, any of the integrated circuits, dice, packages, package-on-packages described herein. The devices 2202, 2204, 2206 illustrated in FIG. 22 are merely exemplary. Other electronic devices may also feature the integrated device 2200 including, but not limited to, mobile devices, hand-held personal communication systems (PCS) units, portable data units such as personal digital assistants, GPS enabled devices, navigation devices, set top boxes, music players, video players, entertainment units, fixed location data units such as meter reading equipment, communications devices, smartphones, tablet computers or any other device that stores or retrieves data or computer instructions, or any combination thereof.

One or more of the components, steps, features, and/or functions illustrated in FIGS. 4, 5, 6, 7, 8, 9, 10, 11, 12, 13A-13E, 14A-14E, 15, 16, 17, 18, 19, 20, 21, and/or 22 may be rearranged and/or combined into a single component, step, feature or function or embodied in several components, steps, or functions. Additional elements, components, steps, and/or functions may also be added without departing from the disclosure. It should also be noted that FIGS. 4, 5, 6, 7, 8, 9, 10, 11, 12, 13A-13E, 14A-14E, 15, 16, 17, 18, 19, 20, 21, and/or 22 and its corresponding description in the present disclosure is not limited to dies and/or ICs. In some implementations, FIGS. 4, 5, 6, 7, 8, 9, 10, 11, 12, 13A-13E, 14A-14E, 15, 16, 17, 18, 19, 20, 21, and/or 22 and its corresponding description may be used to manufacture, create, provide, and/or produce integrated devices. In some implementations, an integrated device may include a die, a die package, an integrated circuit (IC), an integrated package device, a wafer, a semiconductor device, a package on package, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a substrate;
a plurality of lower level metal layers;
a plurality of lower level dielectric layers; and
a redistribution portion comprising:
a first dielectric layer comprising a first dielectric thickness; and
an electromagnetic (EM) passive device comprising a first redistribution interconnect, wherein the first redistribution interconnect comprises a first redistribution thickness, the first dielectric thickness being at least about 2 times (2×) greater than the first redistribution thickness.

2. The integrated device of claim 1 further comprises a radio frequency (RF) shield.

3. The integrated device of claim 2, wherein the RF shield is located between a passivation layer and the plurality of lower level dielectric layers.

4. The integrated device of claim 2, wherein the RF shield is located between the EM passive device and the plurality of lower level dielectric layers.

5. The integrated device of claim 2, wherein the RF shield is coupled to an interconnect configured to provide an electrical path for a ground signal.

6. The integrated device of claim 1, wherein the EM passive device further comprises a second redistribution interconnect.

7. The integrated device of claim 1, wherein the integrated device is one of at least a die and/or a wafer level package integrated device.

8. The integrated device of claim 1, wherein the EM passive device includes one of at least an inductor, a coupler and/or a transformer.

9. The integrated device of claim 1, wherein the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

10. A method for fabricating an integrated device, comprising:
providing a substrate;
forming a plurality of lower level metal layers;
forming a plurality of lower level dielectric layers; and
forming a redistribution portion, wherein forming the redistribution portion comprises:
forming a first dielectric layer comprising a first dielectric thickness; and
forming an electromagnetic (EM) passive device by forming a first redistribution interconnect, wherein the first redistribution interconnect comprises a first redistribution thickness, the first dielectric thickness being at least about 2 times (2×) greater than the first redistribution thickness.

11. The method of claim 10 further comprises forming a radio frequency (RF) shield.

12. The method of claim 11, wherein the RF shield is located between a passivation layer and the plurality of lower level dielectric layers.

13. The method of claim 11, wherein the RF shield is located between the EM passive device and the plurality of lower level dielectric layers.

14. The method of claim 11, wherein the RF shield is coupled to an interconnect configured to provide an electrical path for a ground signal.

15. The method of claim 10, wherein the integrated device is one of at least a die and/or a wafer level package integrated device.

16. The method of claim 10, wherein the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.

17. An integrated device comprising:
a substrate;
a plurality of lower level metal layers;
a plurality of lower level dielectric layers;
a radio frequency (RF) shield; and
a redistribution portion comprising:
a first dielectric layer; and
an electromagnetic (EM) passive device comprising a first redistribution interconnect.

18. The interconnect of claim 17, wherein the RF shield is coupled to an interconnect configured to provide an electrical path for a ground signal.

19. The integrated device of claim 17, wherein the integrated device is one of at least a die and/or a wafer level package integrated device.

20. The integrated device of claim 17, wherein the integrated device is incorporated into at least one of a music player, a video player, an entertainment unit, a navigation device, a communications device, a mobile device, a mobile phone, a smartphone, a personal digital assistant, a fixed location terminal, a tablet computer, and/or a laptop computer.
